(19) United States
(12) Patent Application Publication
(10) Pub. No.: US 2019/0074247 A1
(43) Pub. Date: Mar. 7, 2019

(54) PRINTED CIRCUIT BOARD AND METHOD OF PACKAGING THE SAME

(71) Applicant: Chung-Pao WANG, Taichung (TW)

(72) Inventor: Chung-Pao WANG, Taichung (TW)

(21) Appl. No.: 16/182,604

(22) Filed: Nov. 7, 2018

Related U.S. Application Data
(63) Continuation-in-part of application No. 15/099,612, filed on Apr. 15, 2016.

(51) Int. Cl. H01L 23/498; H01L 21/48

(52) U.S. Cl. CPC H01L 23/49827; H01L 23/49838; H01L 21/6835; H01L 21/486; H01L 21/4853; H01L 23/49811

(57) ABSTRACT

A printed circuit board contains: a first insulator including an upper surface, a lower surface, and a blind via passing through the first insulator; a first trace including an upper surface, a lower surface, a first side edge, and a terminal on the lower surface of the first trace; and a first conductive pad including an upper surface, a lower surface, a side edge, and an opening passing through the first conductive pad. The first trace is connected with the upper surface of the first insulator. The terminal correspondingly exposes inside the blind via of the first insulator. The side edge and the lower surface of the first conductive pad are connected with the first insulator, the upper surface of the first conductive pad exposes outside the lower surface of the first insulator, and the opening of the first conductive pad corresponds to the terminal of the first trace.

This application is a Continuation-in-Part of application Ser. No. 15/099,612, filed Apr. 15, 2016.

### BACKGROUND OF THE INVENTION

### Field of the Invention

The present invention relates to a printed circuit board which is capable of reducing thickness after being packaged.

### Description of the Prior Art

Referring to FIGS. 16A to 16C, they show the structure and manufacturing steps of the conventional printed circuit board 5A. FIG. 15A shows the top view of the printed circuit board 5A, FIG. 15B shows the cross-sectional view of FIG. 15A along line C-C, and FIG. 15C shows the cross-sectional view of adding the first conductive material 95 after the printed circuit board 5A in FIG. 15B is finished. In FIGS. 15A and 15B, the printed circuit board 5A may comprises a first insulator 40, two first traces 70, a second trace 7A, a solder mask 80, and three protective layers 90. The first insulator 40 includes an upper surface 41, a lower surface 42, and a blind via 44 which is penetrated through said insulator 44. A lower surface 72 of each of the first trace 70 is bonded to the upper surface 41 of the first insulator 40. The lower surface 72 further includes a second lower surface 722. At least a portion of the second lower surface 722 is exposed to the blind via 44 of the first insulator 40. The second lower surface 722 may be employed as a conductive pad 3A which is provided for electrically connecting with other conductors such as solder ball, conductive paste, conductive layer or the like. The second trace 7A is arranged at the upper surface 41 of the first insulator 40 and located between the two first traces 70. The solder paste 80 is arranged at the upper surface 41 of the first insulator 40. A portion of the upper surface 71 of the first trace 70 is not covered by the solder mask 80 in order to be exposed to the atmosphere for external connection such as tin, nickel, conductive wire, conductive bump, conductive layer, solder ball, or other suitable conductors. Each of the protective layers 90 is bonded to the upper surface 71 and the second lower surface 722 of the first trace 70 which are exposed to the atmosphere. The protective layer 90 is generally composed of at least staking nickel and gold. For example, the four limitations of the printed circuit board 5A are described as followed. Firstly, the distance P between the two conductive pads 3A (the second lower surface 722 of the first trace 70) is 500 .mu.m. Secondly, the width K of the conductive pad 3A is 250 .mu.m. Thirdly, the width W of the second trace 7A is 50 .mu.m. Fourthly, the distance (not numbered) between the second trace 7A and the first trace 70 is not smaller than 50 .mu.m. Since the width K of the conductive pad 3A is 250 .mu.m, the width D of the blind via 40 is 250 .mu.m too. In order to prevent the first trace 70 from dropping into the blind via 44 of the first insulator 40 to result in damage. The width L of the first trace 70 which is arranged corresponding to the blind via 44 must add more 100 .mu.m compared to the width D of the blind via 44 so that the smallest width L is 350 .mu.m and the smallest distance S between the two first traces 70 is 150 .mu.m. Therefore, only one second trace 7A may be arranged between the two first traces 70 so that the printed circuit board 5A is not good to the circuit with high density, therefore the application of said printed circuit board 5A is restricted, meanwhile, When the protective layer 90 is bonded to the first trace 70 by electroplating, the protective layer 90 must bonded to the second lower surface 722 of the first trace 70 so that the cost of the printed circuit board 5A is increased. In FIG. 15C, a process of filling the first conductive material 95 (such as solder paste) with solder balls in the blind via 44 is provided. The first conductive material 95 is viscous before filling into the blind via 44. The gas 97 may be sealed in the blind via 44 while filling the first conductive material 96 into the blind via 44. When the first conductive material 95 is heated before solidifying, the gas 97 will be expanding by heat. When the first conductive material 95 is forced out of the blind via 44 by the expending gas 97, parts of the conductive material 95f is forced out of the blind via 44 and dropped onto the lower surface 42 of the first insulator 40. If the conductive material 95f which is forced out is not removed, the conductive material 95f may be arranged between two solder balls 96 to electrically connect with the two solder balls 96 to result in the damage of short circuit while the two solder balls 96 are bonded to the printed circuit board 5A. Besides, when the width D of the blind via 44 is larger, the rigidity of the first insulator 40 is easy to become weaker. The first insulator 40 is easy to be bent and broken. When the quantity of the blind via 44 is more, it is easier to result in bending and damaging the first insulator 40. According to above descriptions, the printed circuit board 5A is not easy to increase the density of the circuit and reduce the cost. The first insulator 40 is easy to be bent and the short circuit may also be occurred easily.

A conventional package substrate is disclosed in US Publication No. 20150145131 A1 and contains a core layer, a first ball land pad, a dummy ball lands, and an opening penetrates the core layer to expose the first ball land pad, wherein the first ball land pad disposed on the first surface of the core layer, and the dummy ball land disposed on the second surface of the core layer (refer to FIG. 1B), in this manner, the substrate is a three-layered substrate, then 1). The thickness of the substrate becomes thicker, it is restricted for the substrate being used in the electronic industries, because it is difficult for the substrate to be complied with the demand of “thinness” in the electronic industries; and 2). Due to the dummy ball land is coupled with the second surface of the core layer (refer to FIG. 1A-FIG. 15) by means of one surface of the dummy ball land (i.e. the lower surface of the dummy ball land) exclusively, as this result, it is easy to be caused a peel-off problem of the substrate, because it is easy for the dummy ball land to be peeled off the second surface of the core layer, while the solder ball (refer to FIG. 13C) coupled with the dummy ball land is suffered by a physical force such as a collision, Once the peel-off problem occurs, then the substrate is malfunctioned and/or damaged, For solving the peel-off problem mentioned above, a solder mask (refer to FIG. 7) is invited therein usually, the solder mask is coupled with both the second surface of the core layer and the dummy ball land, wherein the side edge of the dummy ball land and the upper surface of the dummy ball land are covered with the solder mask, thus the areas coupled with the dummy ball land are increased, as this result, the dummy ball land can be fixed on the second surface of the core layer more securely, then, the peel-off problem mentioned above can be solved; Nevertheless, it makes the thickness of the substrate even more thicker, therefore it is worse for the substrate to be used in the electronic industries.

The present invention has arisen to mitigate and/or obviate the afore-described disadvantages.

### SUMMARY OF THE INVENTION

The primary objective of the present invention is to provide a printed circuit board which is capable of reducing thickness after being packaged.

Another objective of the present invention is to provide a printed circuit board in which the first conductive pad and the first insulator are connected securely to avoid the first conductive pad peeling off from the first insulator.

### BRIEF DESCRIPTION OF THE DRAWINGS

All the objects, advantages, and novel features of the invention will become more apparent from the following detailed descriptions when taken in conjunction with the accompanying drawings.

FIGS. 1-1 to 1-3 are the top view and cross-sectional view of a predetermined blind via area or a blind via of a printed circuit board of the present invention.

FIGS. 2-1 to 2-3B are the cross-sectional view and bottom view of a predetermined vent area or a vent of the printed circuit board of the present invention.

FIG. 3 is a cross-sectional view of the printed circuit board of the present invention with elements (or a member).

FIGS. 4-1 to 5 are a cross-sectional view of the printed circuit board of the present invention without a conductive pad.

FIGS. 6A-1 to 6C-2 are the bottom view and cross-sectional view of the real vent and a gate of the printed circuit board of the present invention.

FIGS. 7A-1 to 7B-3 are the three-view diagrams of the printed circuit board of the present invention with shapes of real blind via.

FIGS. 8A-1 to 8B-2 are the top view and the cross-sectional view of the printed circuit board of the present invention with a second insulator.

FIGS. 9 to 10 are the cross-sectional views of the printed circuit board of the present invention with a second side edge.

FIGS. 11 to 14C are the cross-sectional views of drilling process for a predetermined blind via of the first insulator being become a blind via of the first insulator of the present invention.

FIGS. 15A to 15D are the cross-sectional views of the printed circuit board of the present invention which does not include the vent of FIGS. 2-2 to FIG. 2-3B.

FIGS. 16A to 16C are the top view and the cross-sectional view of a conventional printed circuit board.

### DETAILED DESCRIPTION OF THE PREFERRED EMBODIMENTS

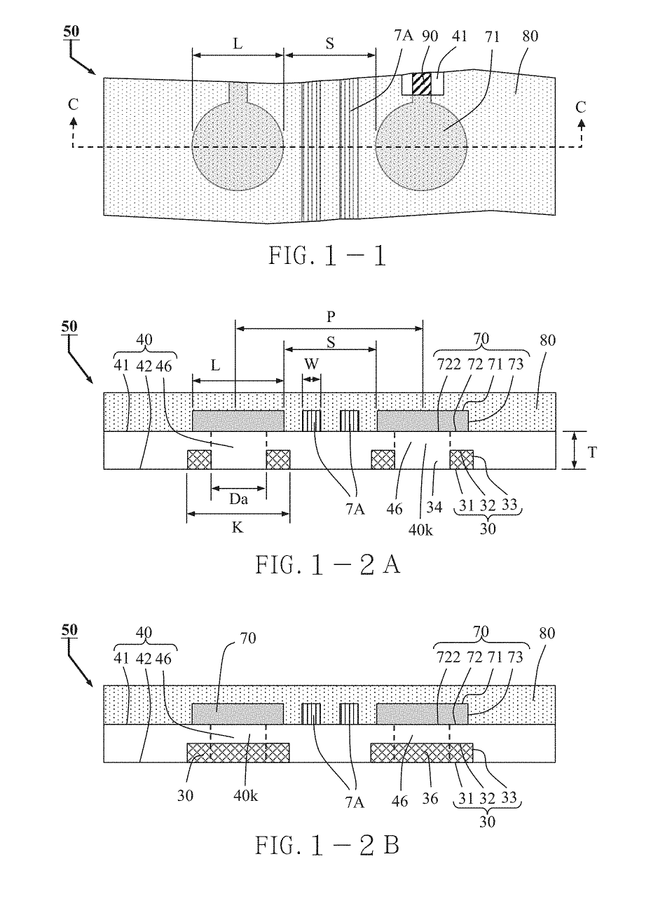

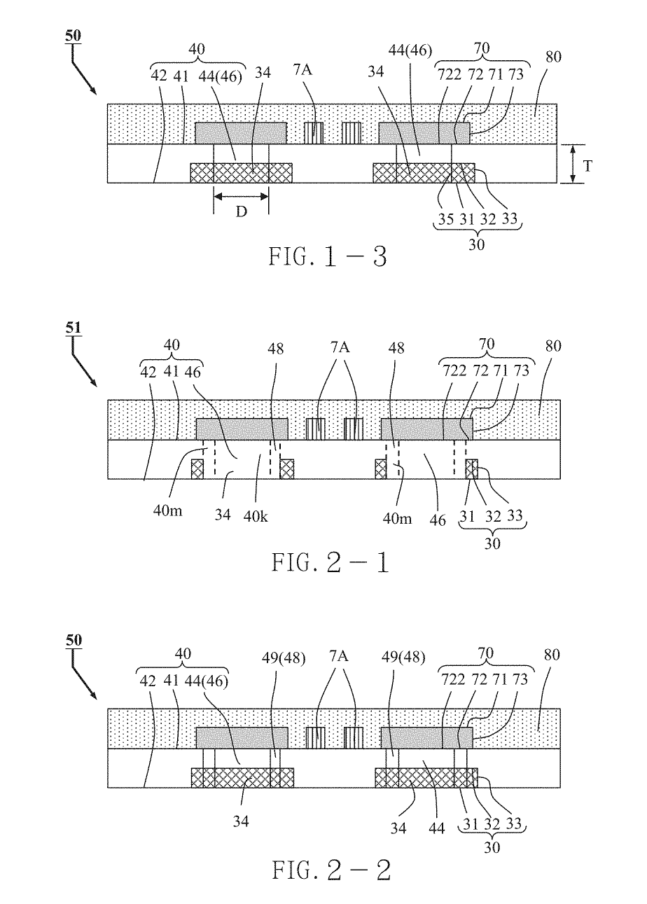

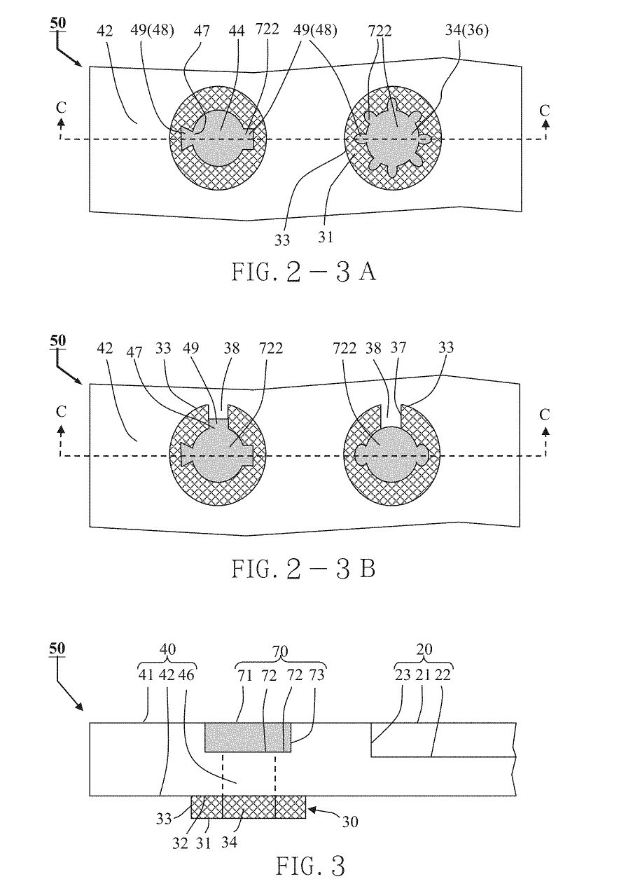

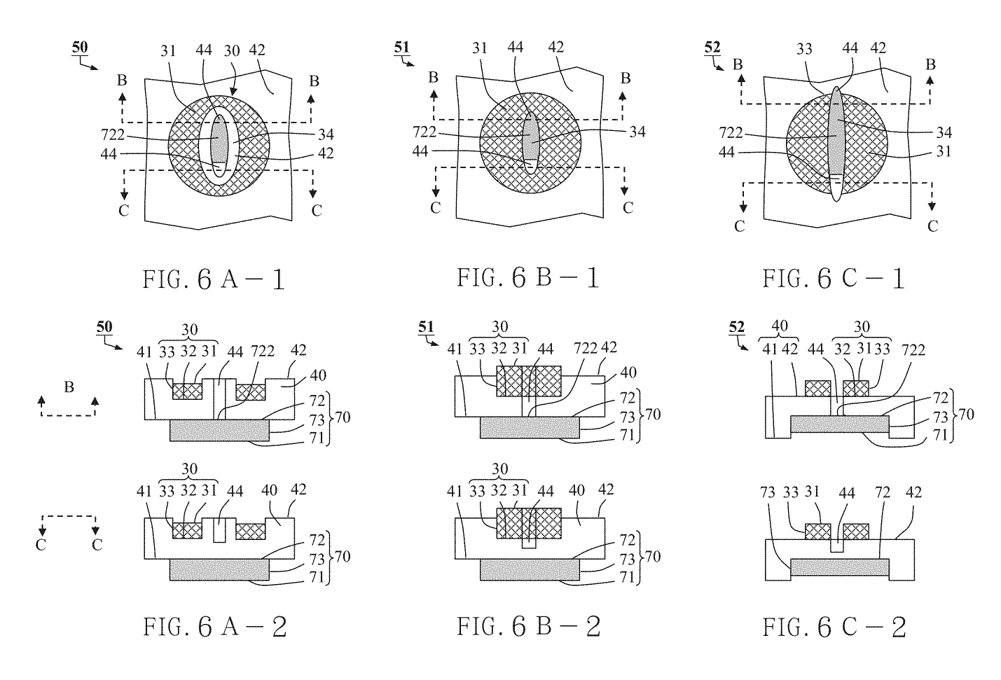

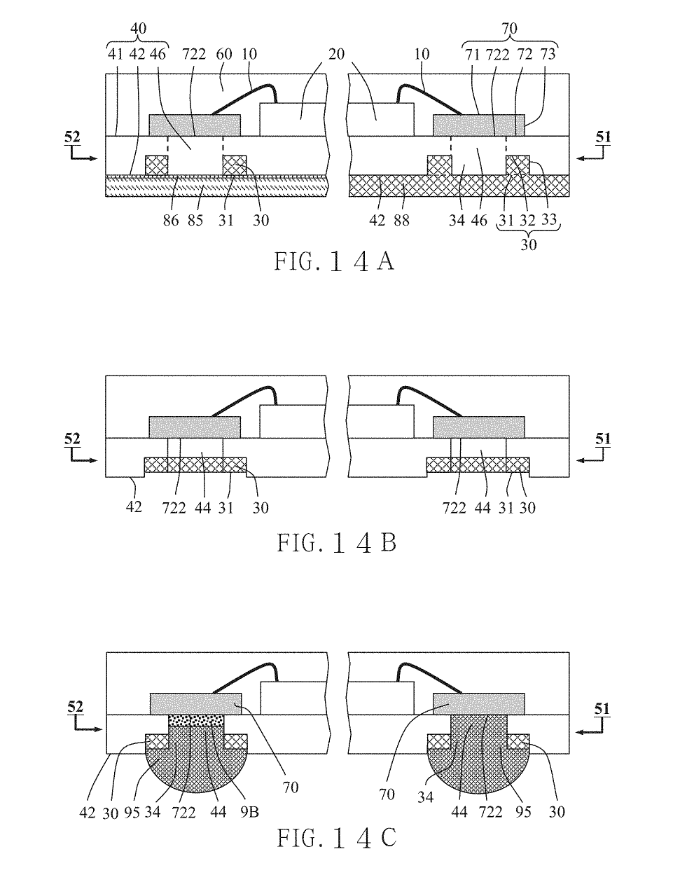

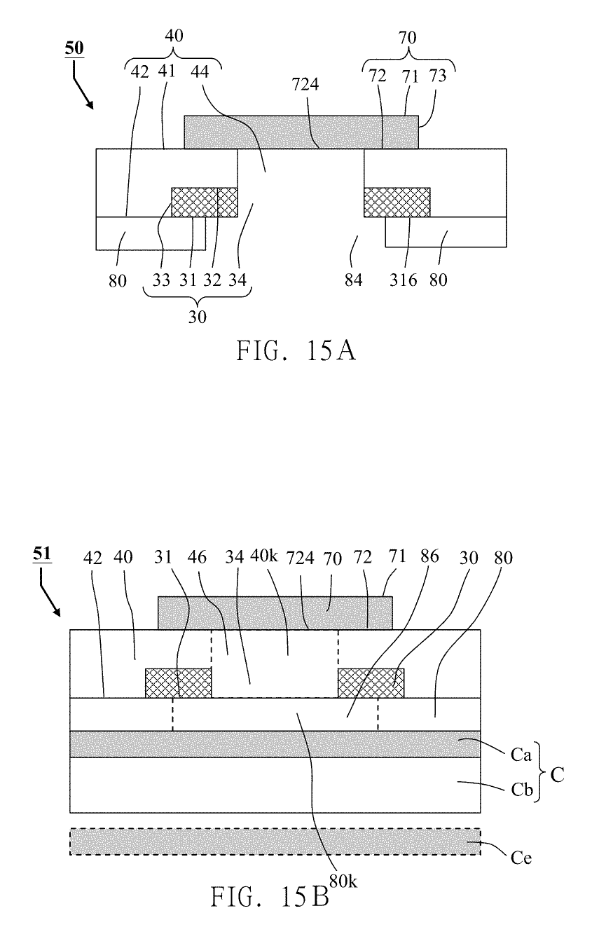

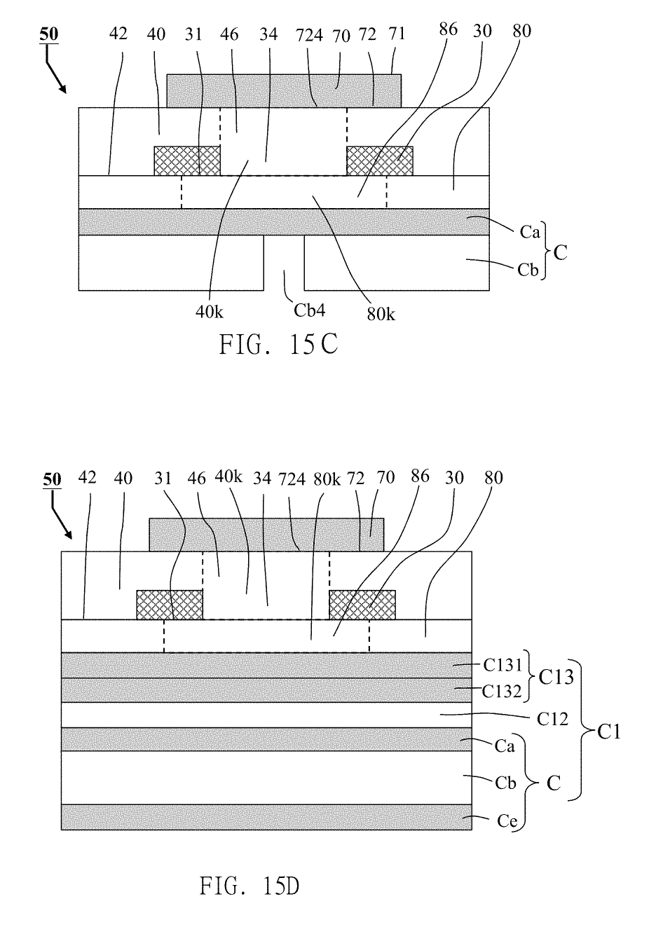

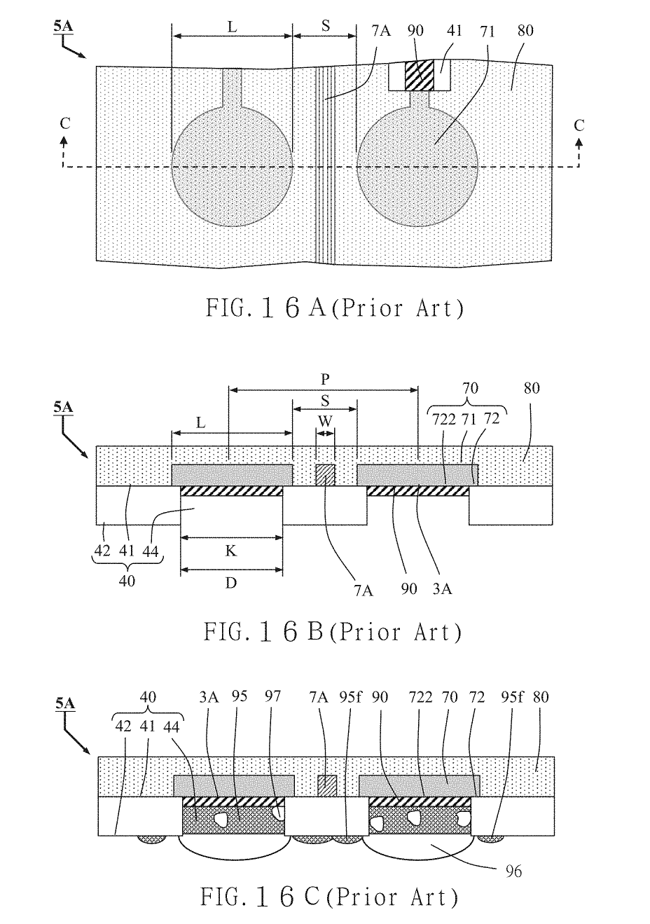

Referring to FIGS. 1-1 to 1-3, they are shown the structure of printed circuit board 50 and the steps which are related to the first trace 70 of printed circuit board 50 electrically connected to the first conductive pad 30 of printed circuit board 50. FIG. 1-1 is a bottom view of the printed circuit board 50. FIG. 1-2A is a cross-sectional view of FIG. 1-1 along line C-C. FIG. 1-2B is another bottom view along line C-C. FIG. 1-3 is a cross-sectional view of the printed circuit 50 with a blind via 44. Firstly, Referring to FIGS. 1-1, 1-2A, and 1-2B, the printed circuit board 50 comprises two first traces 70, a first insulator 40, two second traces 7A, a solder mask 80, a first conductive pad 30, and a protective layer 90. Each of the first trace 70 may be made of copper, metal or other suitable conductors and has a first side edge 73, an upper surface 71, and a lower surface 72. A portion of the lower surface 72 is employed as a second lower surface 722, in this manner, the first trace 70 having a second lower surface 722 which is a portion of the lower surface 72 of the first trace 70, at least a portion of the upper surface 71 of each first trace 70 is provided for electrically connecting with conductive elements such as a tin material, a wire, a bump, a lead, a solder ball, a conductive layer, an another trace, or other suitable conductor(s). The first insulator 40 includes an upper surface 41, a lower surface 42, and a predetermined blind via area 46 (shown with dashed line) which is comprised of an obstructer 40k, the obstructer 40k is received in the predetermined blind via area 46 and is formed by a portion of the first insulator 40. In this manner, the predetermined blind via area 46 is solid, the obstructer 40k is coupled with the second lower surface 722 of the first trace 70 temporarily, and the obstructer 40k received in the predetermined blind via area 46 of the first insulator 40 is prepared (ready) for being removed from the predetermined blind via area 46 of the first insulator 40, meanwhile, the second lower surface 722 of the first trace 70 is used for being electrically connected to a conductive material, wherein at least a portion of the conductive material being exposed to the atmosphere eventually, Once the predetermined blind via 46 becomes a blind via (numeral 44, refer to FIG. 1-3) which is penetrated through the first insulator 40, then, the second lower surface 722 of the first trace 70 enables to be received in the blind via 44 of the first insulator 40 and exposed to the atmosphere for being electrically connected to an external connection (such as a tin material, a wire, a bump, a lead, a solder ball, a conductive layer, an another trace, or the like) which is exposed to the atmosphere, The predetermined shape of the predetermined blind via area 46 may be circle, rectangular, and square, but not limited thereto, wherein a portion of the predetermined blind via area 46 of the first insulator 40 enables to protrude the side edge 33 of the first conductive pad 30 as demanded (the advantages of predetermined blind via area 46 of the first insulator 40 protruding the side edge 33 of the first conductive pad 30, refer to the descriptions of FIG. 6C-1). The first trace 70 is arranged at the upper surface 41 of the first insulator 40. The lower surface 72 of the first trace 70 is bonded to the first insulator 40. The predetermined blind via area 46 of the first insulator 40 is arranged corresponding to the second lower surface 722 of the first trace 70 and the obstructer 40k of the predetermined blind via area 46 is coupled with the second lower surface 722 of the first trace 70 so that the second lower surface 722 of the first trace 70 is not exposed to the atmosphere. Each of the second trace 7A is arranged at the upper surface 41 of the first insulator 40 and located between the two first traces 70. The solder mask 80 is situated on both the upper surface 41 and the upper surface 71 of the first trace 70, wherein at least a portion of the upper surface 71 of the first trace 70 is not covered by the solder mask 80 in order to be exposed to the atmosphere for being electrically connected to the external connection such as tin, nickel, conductive wire, conductive bump, conductive layer, solder ball, solder paste, or other suitable conductors. The solder mask 80 may be designed as demanded. Each of the first conductive pads 30 may be made of copper, metal or other conductors. The two first conductive pads 30 are arranged at the lower surface 42 of the first insulator 40. At least a portion of the first conductive pad 30 is arranged corresponding to the lower surface 72 of the first trace 70. The first conductive pad 30 includes a side edge 33, an upper surface 31, and a lower surface 32. The first conductive pad 30 shown as in FIG. 1-2A has an opening 34 which is penetrated through the first conductive pad 30, at least a portion of the opening 34 is arranged corresponding to the second lower surface 722 of the first trace 70. An object received in the opening 34 is formed by a portion of the first insulator 40. The first insulator 30 shown as in FIG. 1-2B has a predetermined opening 36 (shown as the dashed line). An object received in the predetermined opening 36 is formed by a portion of the first conductive pad 30. The printed circuit board 50 of the present invention may be selected from either the first conductive pad 30 of FIG. 1-2A or the first conductive pad 30 of FIG. 1-2B. The lower surface 32 and the side edge 33 of the first conductive pad 30 are both bonded to the first insulator 40 so that the upper surface 31 of the first conductive pad 30 is exposed out of the lower surface 42 of the first insulator 40 and the upper surface 31 of the first conductive pad 30 may be flatly, concavely, or convexly arranged at the lower surface 42 of the first insulator 40. The protective layer 90 (shown as in FIG. 1-1) is only arranged at the portion of the upper surface 71 of the first trace 70 which is exposed to the atmosphere. Referring to FIG. 1-3, after finishing the process shown in FIG. 1-2A or FIG. 1-2B, a process of drilling (not shown) which is mechanical, laser-like, or chemical is provided so as to make the predetermined blind via area 46 become a blind via 44 which is penetrated through the first insulator 40, wherein all of the obstructers in the predetermined via area 46 associated with the openings 34, the predetermined opening 36 are removed respectively, and the predetermined opening 36 of the first conductive pad 30 also becomes an opening 34 which is a through hole, then the opening 34 of the first conductive pad 30 corresponds to the blind via 44 of the first insulator 40, and the blind via 44 of the first insulator 40 is arranged corresponding to the second lower surface 722 of the first trace 70 so that the second lower surface 722 of the first trace 70 is received in the blind via 44 of the first insulator 40 and is exposed to the atmosphere for being electrically connected to a conductive material (such as a tin, nickel, conductive wire, conductive bump, conductive layer, solder ball, solder paste, or other suitable conductors), wherein at least a portion of the conductive material being exposed to the atmosphere, and a predetermined shape of the blind via 44 may be circle, rectangular, or square, but not limited thereto. Meanwhile, the area of predetermined shape of the real via 44 of the first insulator 40 may be equal to the area of the second surface 722 of the first conductive trace 70; Accordingly, the second lower surface 722 of the first trace 70 is exposed to the blind via 44, The opening 34 of the first conductive pad 30 in FIG. 1-2A may be performed by removing an obstructer arranged inside thereof before the predetermined blind via area 46 becomes the blind via 44. The predetermined opening 36 of the first conductive pad 30 in FIG. 1-2B may be performed by removing an obstructer arranged inside thereof so as to become the opening 34 before the predetermined blind via area 46 becomes the blind via 44. According to above descriptions and the four designs of the printed circuit board 5A in FIGS. 15A to 15C, it shows that the printed circuit board 50 is better than the printed circuit board 5A. The reasons are described as follows. Firstly, the quantities of the second traces 7A may be increased. The widths of the first conductive pad 30 and the first conductive pad 3A of the printed circuit board 5A are both equal to 250 .mu.m, the width Da of the predetermined blind via area 46 of the first insulator 40 in FIG. 1-2A is smaller than the width K of the first conductive pad 30 because the first conductive pad 30 of the printed circuit board 50 is arranged at the lower surface 42 of the first insulator 40. In general, the width Da of the predetermined blind via area 46 is ranged between 65 .mu.m and 200 .mu.m. In order to prevent the first trace 70 from dropping into the blind via 44 (shown as in FIG. 1-3), the width L of the two first traces 70 arranged corresponding to the predetermined blind via area 46 is wider than the width Da of the predetermined blind via area 46 about 100 .mu.m, then the width L of the first trace 70 is between 165 .mu.m and 300 .mu.m, in case that the width L of the first trace 70 is 250 .mu.m. The smallest distance S between the two first traces 70 is 250 .mu.m so that the area between the two first traces 70 may be received the two second traces 7A (50+50+50+50+50=250 .mu.m). Compared to the printed circuit board 5A, the printed circuit board 50 may be arranged another second trace 7A. Secondly, the cost of the protective layer 90 is reduced. The second lower surface 722 of the first trace 70 is not exposed to the atmosphere while the protective layer 90 is arranged so that the protective layer 90 is not bonded to the second lower surface 722 of the first trace 70 and further the usage of quantities and the cost of the protective layer 90 may be reduced. Thirdly, the bonding strength of the conductive material and the first conductive pad 30 may be enhanced, because a first conductive material 95 may be bonding to both the second lower surface 722 of the first trace 70 and the upper surface 31 of the first conductive pad 30 due to the first conductive material 95 filled into the blind via 44 of the first insulator 40, the bonding area and strength of the first conductive pad 30 may be enhanced through a side wall 35 (shown as in FIG. 1-3) of the opening 34 of the first conductive pad 30 and further the quality of the printed circuit board may be improved. Fourthly, nowadays, the size of the development trend of the electronic devices is light, thin, short, and small shown as in FIG. 1-2A. In case that the thickness T of the first insulator 40 is smaller than 100 .mu.m, the rigidity may be increased to prevent the first insulator 40 from being bent and broken to damage because the predetermined blind via area 46 has not become the blind via 44 yet, so that the first insulator 40 is still a whole complete insulator without any through hole (i.e. blind via). At the same time, even when the quantities of the blind vias are more, it may also prevent the first insulator 40 from being bent and broken to damage. In general, when the thickness T of the first insulator 40 is smaller than 100 .mu.m and the width D (shown as in FIG. 1-3) of the blind via 44 is equal to 200 .mu.m, that is, the ratio of the thickness T of the first insulator 40 to the width Da (shown as in FIG. 1-2A) of the predetermined blind via area 46 is not lager than 0.5 (i.e. equal to or smaller than 0.5; T/Da.1toreq.0.5), it is easy to be bent and broken to damage because the rigidity of the first insulator 40 is not enough. The rigidity of the first insulator 40 may be increased to reduce or prevent from above mentioned problems by increasing the thickness T of the first insulator 40 or arranging the predetermined blind via area 46 at the first insulator 40. However, the materials and the manufacturing cost may be needed more to increase the thickness T of the first insulator 40 and it is not good to the development trend of electronic industries. Nevertheless, in case that the first insulator 40 has the predetermined blind via area 46, the rigidity of the first insulator 40 may be increased while the thickness T is not changed. Therefore, it may use less material and further prevent the first insulator 40 from being bent and broken, and it is also useful for the development of electronic industries. When the first insulator 40 has the predetermined blind via area 46, the ratio of the thickness T of the first insulator 40 to the width Da of the predetermined blind via area 46 is not larger than 0.5 (T/Da.1toreq.0.5, or smaller than 0.4, or between 0.30 and/or 0.01 etc.), it may reduce or prevent the first insulator 40 from being bent and broken to damage. wherein in case that the predetermined blind via 46 of the first insulator 40 having a plurality of widths Da with different dimensions, then the width Da of the predetermined blind via 46 of the first insulator 40 herein is the largest one; Moreover, as shown in FIG. 1-3, in case that the predetermined blind via area 46 has already been become the blind via 44, then the ratio of the thickness T of the first insulator 40 to the width D of the blind via area 44 also enables to be not larger than 0.5 (T/D.1toreq.0.5), in this manner, the printed circuit board 50 may be more practical, wherein the width D of blind via 44 is equal to (or close to) the width Da of predetermined blind via 46; Additionally, the upper surface or the lower surface of the printed circuit board of the present invention (such as the surface of the first insulator 40 exposed to the atmosphere) may be connected with the carrier sheet(s) (numbered as 85, 88, shown as in FIG. 14A) or the printed circuit board may be not arranged the first conductive pad 30 (shown as in FIGS. 4-1 to 5) so as to make the printed circuit board more practical.

Referring to FIG. 2-1, it shows a cross-sectional view of the printed circuit board 51. The structure and the numbers of the printed circuit board 51 are almost the same as them of the printed circuit board 50 shown in FIG. 1-2A. The difference therebetween is described as follows. The printed circuit board 51 has a plurality of predetermined vent areas 48 which are arranged at the peripherals of the predetermined blind via areas 46 of the first insulator 40 and located adjacent to the predetermined blind via areas 46 respectively. That is, each predetermined blind via area 46 further includes the predetermined vent areas 48, wherein each predetermined vent area 48 is comprised of an obstructer 40m, the obstructer 40m is received in the predetermined vent area 48 and is formed by a portion of the first insulator 40. In this manner, each predetermined vent 48 is solid, each predetermined vent area 48 of the first insulator 40 is arranged corresponding to the second lower surface 722 of the first trace 70, and each obstructer 40m of the predetermined vent area 48 is coupled with the second lower surface 722 of the first trace 70.

Referring to FIGS. 2-2, 2-3A, and 2-3B, FIGS. 2-3A and 2-3B are the bottom views of the printed circuit board 50, and FIG. 2-2 is the cross-sectional view of FIG. 2-3A or 2-3B along line C-C. The descriptions are as follows. The printed circuit board 50 in FIG. 2-2 is operated by providing a process of drilling (not shown) after the printed circuit board 51 in FIG. 2-1 is finished. By the process of drilling, the objects arranged in the predetermined blind via area 46 and the predetermined vent area 48 are removed so that both the predetermined blind via area 46 becomes the blind via 44 and the predetermined vent area 48 becomes the vent 49 which is penetrated through the first insulator 40, in this manner, the vent 49 is a through hole. The shape of blind via 44 associated with the vent 49 is the same as the shape of the predetermined blind via area 46 associated with the predetermined vent area 48 (refer to FIG. 2-3A or FIG. 2-3B). Furthermore, the first insulator 40 of the printed circuit board 50 further includes the vent(s) 49 and the gate(s) 47. The gate 47 is arranged between the blind via 44 and the vent(s) 49 so that the blind via 44 is fluidly communicated with the vent(s) 49. The blind via 44 further includes the vent(s) 49 and the gate 47. A portion of the second lower surface 722 of the first trace 70 is exposed to the blind via 44 and the other part thereof is exposed to the vent(s) 49. Referring to FIGS. 6A-1 to 6C-2 (the cross-sectional view along line C-C), a portion of the first insulator 40 is arranged between the first trace 70 and the vent(s) 49 as demanded, in this manner, the vent 49(s) in FIG. 6A-1 to FIG. 6c-2 is not penetrated. In FIG. 2-3A, the peripheral of the blind via 44 may have one or more vents 49. At least a portion of the vent(s) 49 is arranged corresponding to the opening 34 of the first conductive pad 30. Besides the gate 47 may provide the gas or chemical solvents in the blind via 44 to flow into the vent(s) 49, it may also limit the conductive material flowed into the vent(s) 49 by changing the width of the gate 47 so as to increase the quality of the printed circuit board 50. Especially, when the conductive material includes solder paste with tin particles or other metals, the effects of the gate 70 may be effectively appeared. For example, in case that the diameter of the tin particle in the solder paste is 75 .mu.m, the width of the gate 47 may be designed to smaller than 70 .mu.m or much smaller so that the tin particle with 75 .mu.m diameter may be limited in the blind via 44 by the gate 47 and the gas (numbered as 97 in FIG. 15C) or the chemical solvents may be only flowed into the vent(s) 49. Accordingly, when the printed circuit board 50 is heated, the gas or the chemical solvents sealed in the blind via 44 of the insulator 40 may be passed through the gate 47, the vent(s) 49 of the first insulator 40, and the lower surface 42 of the first insulator 40 to directly exhaust to the atmosphere. Therefore, the gas sealed in the blind via 44 may be effectively reduced and the quantities of the tin particles which are forced out of the blind via 44 due to the expanding gas are effectively reduced. And further, it may prevent the tin materials from dropping onto the lower surface of the printed circuit board 50 to result in the damage of short circuit. The reason is the volume of the gas may be obviously increased by heating. If the time of the gas stayed in the blind via 44 of the first insulator 40 is longer, the volume of the gas is larger and the pressure in the blind via 44 of the first insulator 40 is higher. Therefore, the tin particles in the solder paste may be forced out of the blind via 44 of the first insulator 40 and then dropped onto the surface of the printed circuit board 50 so as to result in the damage of short circuit of the printed circuit board 50. Moreover, the blind via 44 of the first insulator 40 of printed circuit board 50 in FIG. 2-3A further having both a width D1 and a length H (the advantages of the width D1 and the length H are described in the descriptions of FIG. 7B-1 to FIG. 7B-3), wherein the width D1 of blind via 44 is shorter than the length H of blind via 44; The difference of the bottom view in FIG. 2-3B and the bottom view in FIG. 2-3A is the first conductive pad 30. The first conductive pad 30 in FIG. 2-3B includes a groove 38 and a groove wall 37. The groove 38 is passed through the first conductive pad 30 so that the first conductive pad 30 is not closed. A portion of the first insulator 40 is received in the groove 38 and bonded to the groove wall 37. The object received in the groove 38 is formed by a portion of the first insulator 40. If the vent(s) 49 is needed, the size of the vent(s) 49 may be designed as demanded and then the object received in the groove 38 is partially or totally removed so that the vent(s) 49 may be more elastic. In FIGS. 2-3A and 2-3B, the opening 34(36) of the first conductive pad 30 may be a predetermined shape, such as circle, rectangular, and square, but not limited thereto, Besides, according to the descriptions of FIGS. 2-1,2-2 and 2-3A, The predetermined blind via area 46 also having a width D1 and a length H, the width D1 of predetermined via area 46 is shorter than the length H of predetermined via area 46; In addition, the first conductive pad 30 shown in FIG. 2-3B is made of a conductive metal and is not closed, in this manner, a portion of the vent 49 of the first conductive pad 30 may be able to protrude the side edge 33 of the first conductive pad 30, then the area of the vent 49 may be able to get larger, as this result, it is good for the vent 49 to be effectively exhausting the gas or chemical solvent in the blind via 44 and further preventing from damage of short circuit.

Referring to FIG. 3, it shows the cross-sectional view of the printed circuit board 50. The printed circuit board 50 comprises the first trace 70, the first insulator 40, the first conductive pad 30, and a member 20 (such as the electronic element). The first trace 70 has the first side edge 73, the upper surface 71, and the lower surface 72. A portion of the lower surface 72 is employed as a second lower surface 722. A portion of the upper surface 71 of each first trace 70 is provided for electrically connecting with conductive element(s). The first insulator 40 includes the upper surface 41, the lower surface 42, and the predetermined blind via area 46. The predetermined blind via area 46 is formed by a portion of the first insulator 40. The first trace 70 is arranged at the upper surface 41 of the first insulator 40. At least a portion of the first side edge 73 of the first trace 70 and the lower surface 72 of the first trace 70 are bonded to the first insulator 40. The upper surface 71 of the first trace 70 is exposed out of the upper surface 41 of the first insulator 40. The predetermined blind via area 46 is both arranged corresponding to the second lower surface 722 of the first trace 70 and coupled with the second lower surface 722 of the first trace 70 so that the second lower surface 722 of the first trace 70 is not exposed to the atmosphere. The predetermined blind via area 46 of the first insulator 40 becomes a real blind via (numbered as 44 in FIG. 1-3) through a process of drilling so that the second lower surface 722 of the first trace 70 may be exposed to the blind via 44. The predetermined blind via area 46 may further include a predetermined vent area (numbered as 48 in FIG. 2-1). The first conductive pad 30 is arranged at the lower surface 42 of the first insulator 40. At least a portion of the first conductive pad 30 is arranged corresponding to the lower surface 72 of the first trace 70 and the first conductive pad 30 may include the side edge 33, the upper surface 31, the lower surface 32, and the opening 34. The lower surface 32 is bonded to the first insulator 40. The opening 34 of the first conductive pad 30 may be designed the predetermined opening area (numbered as 36 in FIG. 1-2B) as demanded. The member 20 may be employed as a chip, flip chip, and/or semiconductor package, but not limited thereto. The member 20 may include an upper surface 21, a lower surface 22, and a side edge 23. The upper surface 21 having a plurality of conductive terminal/pad (not shown) for external connection such as a conductive wire and/or conductive bump etc., The member 20 may be electrically connected with the printed circuit board 50 through a conductive mean (numbered as 10 in FIG. 12B). The member 20 is arranged at the upper surface 41 of the first insulator 40. At least a portion of the side 23 and the lower surface 22 are coupled with the first insulator 40. Accordingly, the upper surface 21 of the member 20 may be flatly, concavely, or convexly arranged at the upper surface 41 of the first insulator 40 as demanded. Besides, the first trace 70 may be coupled with the first insulator 40 through both the lower surface 72 and at least a portion of the first side edge 73 of the first trace 70 so that the upper surface 71 of the first trace 70 may be flatly, concavely, or convexly arranged at the upper surface 41 of the first insulator 40. Otherwise, at least a portion of the side edge 33 of the first conductive pad 30 is coupled with the first insulator 40 so that the upper surface 31 of the first conductive pad 30 may be flatly, concavely, or convexly arranged at the lower surface 42 of the first insulator 40. Moreover, The peripheral of the predetermined blind via area 46 of the first insulator 40 may be arranged the predetermined vent area 48 or blind via 44 the predetermined blind via area 46 is replaced by the blind via 44, or the vent 49 is replaced by the predetermined vent area 48; Furthermore, the member 20 may be coupled with the insulator 40 by the side edge 23 of member 20 exclusively, in this manner, the lower surface 22 of member 20 enables to be exposed out of the lower surface 42 of the first insulator 40 so as to enhance the dissipation of heat generated by the member 20.

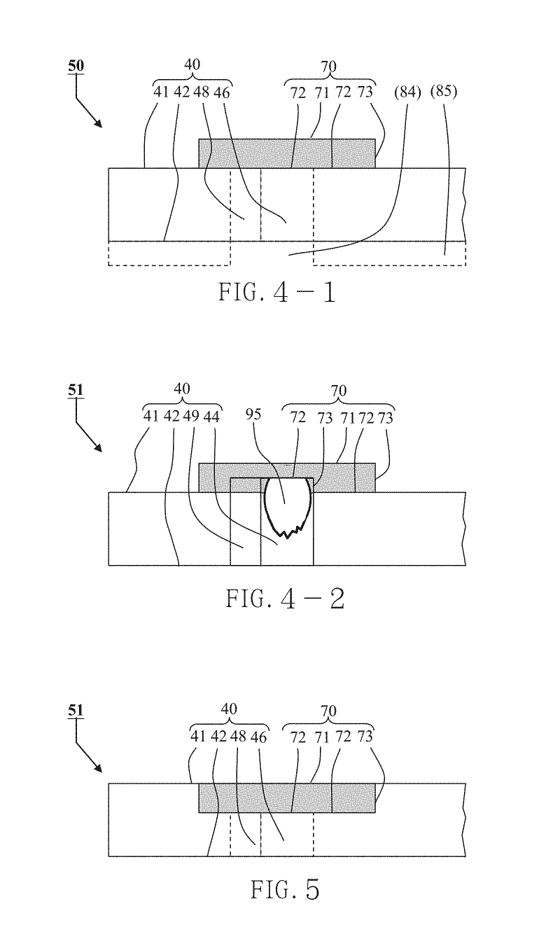

Referring to FIGS. 4-1 to 4-2, they show the cross-sectional views of the printed circuit boards 50, 51. The printed circuit boards 50, 51 have the effects of the vent(s) 49 to prevent the printed circuit board 5A in FIG. 15C from the damage of short circuit. The printed circuit board 50 in FIG. 4-1 comprises the first trace 70, the first insulator 40, and a carrier sheet (numbered as 85 with dashed line). The first trace 70 includes the first side edge 73, the upper surface 71, and the lower surface 72. A portion of the lower surface 72 is employed as a second lower surface 722. At least a portion of the upper surface 71 of the first trace 70 may be provided for electrically connecting with conductive elements. The first insulator 40 includes the upper surface, the lower surface 42, and the predetermined blind via area 46. The predetermined blind via area 46 may further include a predetermined vent area 48. The predetermined blind via area 46 and the predetermined vent area 48 are respectively formed by a portion of the first insulator 40. The first trace 70 is arranged at the upper surface 41 of the first insulator 40. The first insulator 40 is bonded to the lower surface 72 of the first trace 70. The predetermined blind via area 46 of the first insulator 40 is arranged corresponding to the second lower surface 722 of the first trace 70 so that the second lower surface 722 of the first trace 70 is not exposed to the atmosphere. The predetermined vent area 48 is arranged adjacent to the predetermined blind via area 46. The carrier sheet 85 may be arranged at the lower surface 42 of the first insulator 40 as demanded so as to increase the rigidity of the printed circuit board 50. At the same time, the carrier sheet 85 may have an opening 84 which is a through hole, wherein the width of the opening 84 enables to be either larger than 5 .mu.m or smaller than 10,000 .mu.m as demanded. Accordingly, a portion of the lower surface 42 of the first insulator 40 is exposed to the opening 84. The opening 84 of the carrier sheet 85 is arranged corresponding to the predetermined blind via area 46. Otherwise, the opening 84 of the carrier sheet 85 is not arranged corresponding to the predetermined blind via area 46. The carrier sheet 85 enables to be removed before the conductive material is provided (shown as in FIGS. 4-2; FIG. 14B and FIG. 14 C) or the carrier sheet 85 enables to be removed or not be removed from the printed circuit board 50, 51 in any suitable time (or step) as demanded, the carrier sheet 85 may not include the opening 84. Next, in FIG. 4-2, a process of drilling (not shown) is provided to the printed circuit board 51 after the printed circuit board 50 in FIG. 4-1 is finished. Wherein the obstructer received in the predetermined blind via area 46 and the predetermined vent area 48 are all removed, then The predetermined blind via area 46 and the predetermined vent area 48 are respectively become the blind via 44 and the vent 49 by the process of drilling. The blind via 44 of the first insulator 40 further includes the vent 49 and the gate (numbered as 47 in FIG. 2-3A). The second lower surface 722 of the first trace 70 is exposed to both the blind via 44 and the vent 49. The carrier sheet 85 is removed and then a first conductive material 95 is provided. The first conductive material 95 is bonded to the second lower surface 722 of the first trace 70. Wherein at least a portion of the first conductive material 95 is received in the blind via 44 of the first insulator 40 and bonded to the second lower surface 722 of the first trace 70 so that the first conductive material 95 is electrically connected with the first trace 70 of the printed circuit board 51. The first conductive material 95 is received in the blind via 44 and bonded to the second lower surface 722 of the first trace 70 by a suitable machine (such as wire blonder). The first conductive material 95 may shorten a distance between the second lower surface 722 of the first trace 70 and the lower surface 42 of the first insulator 40 so that the second lower surface 722 received in the blind via 44 is easier to electrically connect to the outside (such as tin, nickel, conductive wire, conductive bump, lead, solder ball, or other suitable conductors) and further the damage of open circuit of the printed circuit board 51 may be prevented. The first conductive material 95 may be employed as a conductive bump, such as copper bump, gold bump, and/or alloy bump, but not limited thereto. Furthermore, the upper surface (not numbered) of the first conductive material 95 may be stacked one or more conductive bumps (not shown) so as to adjust the distance between the second lower surface 722 of the first trace 70 and the lower surface 42 of the first insulator 40. The first conductive material 95 may be employed as the conductive material (reference to the descriptions of FIG. 14C) as demanded. The preferred embodiment of FIG. 4-2 is that the carrier sheet 85 is removed from the first insulator 40 after the predetermined blind via area 46 and the predetermined vent area 48 are respectively become the blind via 44 and the vent 49 before the first conductive material 95 is provided as demanded. The carrier sheet 85 in FIG. 4-2 may be removed from the first insulator 40 after the member 20 and the encapsulant 60 (reference to the descriptions of FIGS. 14A to 14C) are arranged at one surface of the printed circuit board 50 and before the first conductive material 95 is provided as demanded. Besides, the first trace 70 may (or not) include a second side 732. The second side 732 is arranged between the lower surface 72 and the second lower surface 722. In this manner, the second lower surface 722 is concavely arranged at the lower surface 72 of the first trace 70. Then the area of the first trace 70 exposed to the blind via 44 may be increased due to the arrangement of the second side 732 so that the bonding strength between the first conductive material 95 received in the blind via 44 and the first trace 70 may be increased and the quality of the printed circuit board 51 may be improved. In FIG. 4-1, the printed circuit board 50 may not include the predetermined vent area 48 as demanded. Accordingly, the blind via 44 of the printed circuit board 51 in FIG. 4-2 may not include the vent 49; wherein the carrier sheet 85 in FIG. 4-1 is optional, meanwhile, it may not be necessary for the carrier sheet 85 to be removed from the printed circuit board 50 either.

Referring to FIG. 5, it shows the cross-sectional view of the printed circuit board 51. The characteristics and the numbers of the printed circuit board 51 are similar to them of the printed circuit board 50 in FIG. 4-1. The difference therebetween is described as follows. At least a portion of the first side edge 73 of the first trace 70 is bonded to the first insulator 40 so that the upper surface 71 of the first trace 70 may be flatly, concavely, or convexly arranged at the upper surface 41 of the first insulator 40. Accordingly, the thickness of the printed circuit board 51 may be thinner and more practical. The printed circuit board 51 may not include the predetermined vent area 48 but include the carrier sheet 85 (shown as in FIG. 4-1). The carrier sheet 85 is arranged at one surface of the printed circuit board 51 (such as the lower surface 42 of the first insulator 40). The carrier sheet 85 has the opening 84 so that a portion of the lower surface 42 of the first insulator 40 may be exposed to the opening 84 of carrier sheet 85. The opening 84 of the carrier sheet 85 is arranged corresponding to the predetermined blind via area 46. Accordingly, a process of electrically connecting the first trace 70 with the first conductive material 95 may be provided and the steps are described as follows. Firstly, the member 20 and the encapsulant 60 (shown as in FIG. 12B) are provided. The member 20 and the encapsulant 60 are arranged at the same surface of the printed circuit board 51. The member 20 is arranged at the surface of the printed circuit board 51 so as to electrically connect the member 20 to the printed circuit board 51 (reference to the descriptions of FIG. 12B), and then the encapsulant 60 is covered at least a portion of the member 20. Secondly, a process of drilling is provided (not shown). Then the predetermined blind via area 46 is become the blind via 44 by the process of drilling so that at least a portion of the second surface 722 of the first trace 70 is exposed to the blind via 44. Thirdly, a process of peeling is provided to remove the carrier sheet 85 from the printed circuit board 51. Fourthly, the first conductive material 95 is provided. At least a portion of the first conductive material is received in the blind via 44 and bonded to the second lower surface 722 of the first trace 70 so that the first conductive material 95 is electrically connected to the first trace 70.

Referring to FIGS. 6A-1 to 6C-2, FIGS. 6A-1, 6B-1, and 6C-1 are the bottom views of the three printed circuit board 50, 51, and 52 respectively, and FIGS. 6A-2, 6B-2, and 6C-2 are the cross-sectional views of FIGS. 6A-1, 6B-1, and 6C-1 respectively along lines B-B and C-C. Each of the three printed circuit board 50, 51, and 52 comprises the first trace 70, the first insulator 40, and the first conductive pad 30. The first trace 70 includes the first side edge 73, the upper surface 71, and the lower surface 72. A portion of the lower surface 72 is employed as the second lower surface 722. At least a portion of the upper surface 71 of the first trace 70 is provided for electrically connecting with suitable conductors. The first insulator 40 includes the upper surface 41, the lower surface 42, and the blind via 44. The first trace 70 is arranged at the upper surface 41 of the first insulator 40. In FIG. 6C-2, at least a portion of the first side edge 73 and the lower surface 72 of the first trace 70 of the printed circuit board 52 are bonded to the first insulator 40 so that the upper surface 71 of the first trace 70 is concavely arranged at the upper surface 41 of the first insulator 40. In FIGS. 6A-2 and 6B-2, the lower surface 72 of the first race 70 of each of the printed circuit boards 50, 51 is bonded to the first insulator 40 respectively. At the same time, Referring to the cross-sectional views of the printed circuit boards 50, 51, and 52 of the FIGS. 6A-2, 6B-2, and 6C-2 along line B-B, wherein a portion of the second lower surface 722 of the first trace 70 is exposed to the blind via 44 exclusively. Otherwise, Referring to the cross-sectional views of the printed circuit boards 50, 51, and 52 of the FIGS. 6A-2, 6B-2, and 6C-2 along line C-C, wherein a portion of the first insulator 40 is arranged between the bottom of the blind via 44 and the first trace 70, in this manner, the other portion of the second lower surface 722 of the first trace 70 is not exposed to the blind via 44. The first conductive pad 30 includes the side edge 33, the upper surface 31, and the lower surface 32, and the opening 34. The first conductive pad 30 is arranged at the lower surface 42 of the first insulator 40. At least a portion of the upper surface 31 of the first conductive pad 30 is provided for electrically connecting with suitable conductors. At least a portion of the side 33 and the lower surface 32 of the first conductive pad 30 in FIG. 6A-2 are bonded to the first insulator 40 so that the upper surface 31 of the first conductive pad 30 may be concavely arranged at the lower surface 42 of the first insulator 40. A portion of the lower surface 32 and the side edge 33 of the first conductive pad 30 in FIG. 6B-2 is bonded to the first insulator 40 so that the upper surface 31 of the first conductive pad 30 may be convexly arranged at the lower surface 42 of the first insulator 40. The lower surface 32 of the first conductive pad 30 in FIG. 6C-2 is bonded to the first insulator 40. According to above descriptions, when the first trace 70 or the first conductive pad 30 is arranged at one surface of the first insulator 40, then among at least a portion of the first side edge 73 of the first trace 70, at least a portion of the side edge 33 of the first conductive pad 30, or both the first trace 70 and the first conductive pad 30 are bonded to the first insulator 40 so that the upper surface 71 of the first trace 70 and/or the upper surface 31 of the first conducive pad 30 enables to be flatly, concavely, or convexly arranged at the surface of the first insulator 40 as demanded. In FIG. 6C-1, a portion of the bind via 44 protrudes the side edge 33 of the first conductive pad 30. The first conductive pad 30 comprised of a plurality of metals, then the blind via 44 is between the metals, wherein due to a portion of the bind via 44 protrudes the side edge 33 of the first conductive pad 30, the area of blind via 44 enables not to be restricted in the area of the first conductive pad 30 exclusively, then it allows the blind via 44 to be more practical, moreover, in case of the further having a vent (49), then the area of the vent 49 may be able to get larger, as this result, it is good for the vent (49) to be effectively exhausting the gas or chemical solvent in the blind via and further preventing from damage of short circuit. The first conductive pad 30 has a predetermined shape. The vent(s) (not shown) may be arranged at an area excluding the side edge 33 of the first conductive pad 30. The vent(s) may be fluidly communicated with the blind via 44. Then the blind via 44 further includes the vent(s). Accordingly, the printed circuit board of the present invention may be more practical. Otherwise, in FIG. 6A-1, the width of the opening 34 of the first conductive pad 30 is larger than the width of the blind via 44 so that a portion of the first insulator 40 enables to be received in the opening 34 of the first conductive pad 30 or a portion of the first insulator 40 enables to be not received in the opening 34 of the first conductive pad 30 as demanded. Otherwise, in FIGS. 6A-1 to 6C-1, the peripheral of the blind via 44 of each of the printed circuit boards 50, 51, 52 also enables to include the vent(s) 49 and the gate 47 to prevent the printed circuit board from damage of short circuit.

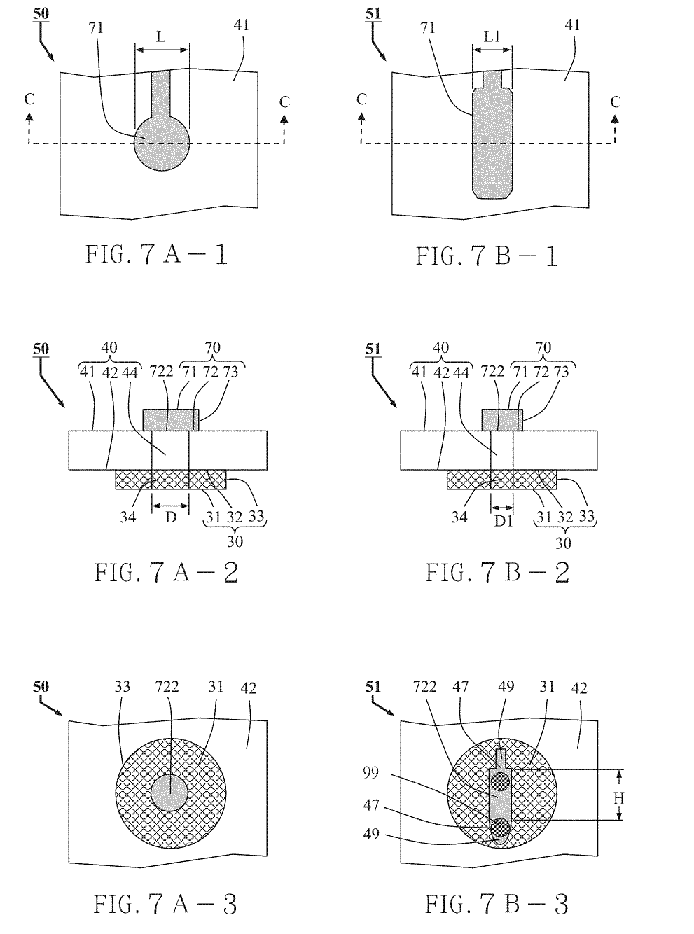

Referring to FIGS. 7A-1 to 7B-3, FIGS. 7A-1 and 7B-1 are the top views of the printed circuit boards 50 and 51, FIGS. 7A-2 and 7B-2 are the cross-sectional views of FIGS. 7A-1 and 7B-1 along line C-C, and FIGS. 7A-3 and 7B-3 are the bottom views of the printed circuit boards 50, 51. Each of the printed circuit boards 50, 51 at least comprises the first trace 70, the first insulator 40, and the first conductive pad 30. The first trace 70 includes the first side edge 73, the upper surface 71, and the lower surface 72. A portion of the lower surface 72 is employed as the second lower surface 722. At least a portion of the upper surface 71 of the first trace 70 is provided for electrically connecting with the suitable conductors. The first insulator 40 includes the upper surface 41, the lower surface 42, and the blind via 44. The first trace 70 is arranged at the upper surface 41 of the first insulator 40. The lower surface 72 of the first trace 70 is bonded to the first insulator 40. The blind via 44 is arranged corresponding to at least a portion of the second lower surface 722 of the first trace 70 so that at least a portion of the second lower surface 722 of the first trace 70 may be exposed to the real blind 44. The first conductive pad 30 includes the side edge 33, the upper surface 31, and the lower surface 32. The first conductive pad 30 is arranged at the lower surface 42 of the first insulator 40. The lower surface 32 is bonded to the first insulator 40. At least a portion of the opening 34 of the first conductive pad 30 is arranged corresponding to the second lower surface 722 of the first trace 70. According to above descriptions and compared with the printed circuit boards 50, 51, another characteristic is appeared. The characteristic is to change the shape of the blind via 44 so as to reduce the width L of the first trace 70 and further to increase the distance S (shown as in FIG. 1-2A) between adjacent two first traces 70. Therefore, more second traces 7A (shown as in FIG. 1-2A) may be arranged between two first traces 70. In general, the shape of real blind vias 44 of the printed circuit boards 50 in FIGS. 7A-1 to 7A-3 which are drilled by the conventional mechanical or laser process are circle or close to circle. The aperture ratio thereof is not smaller than 0.97 or even smaller than 0.5. For example, when the blind via 44 is circle and the width D (shown in FIG. 7A-2) thereof is 100 .mu.m, the aperture ratio of the blind via 44 (shown in FIG. 7A-3) is 1.0 (100/100), then the area of the blind via 44 (i.e. the second lower surface 722 of the first trace 70) is 7,854 .mu.m.sup.2 (3.1416.times.(100/2).sup.2). At the same time, in order not to make the first trace 70 drop into the blind via 44, the width L of the first trace 70 may need to be increased to 200 .mu.m (50+100+50) or more as demanded. Next, the blind via 44 associated with the vent 49 of the printed circuit board 51 in FIGS. 7B-1 to 7B-3 have a predetermined shape (not circle), wherein For better understanding, the shape of the blind via 44 of the first insulator 40 is assumed as a rectangle, in this manner, the blind via 44 of the first insulator 40 of printed circuit board 51 having both a width D1 and a length H, wherein the width D1 of the first blind via 44 of the first insulator 40 is shorter than the length H of the first blind via 44 of the first insulator 40. The vent 49 allows a portion of the second lower surface 722 of the first trace 70 to be exposed to the vent 49 and received therein. At least a portion of the opening 34 of the first conductive pad 30 is arranged corresponding to the vent 49. The blind via 44 is arranged corresponding to at least a portion of the second lower surface 722 of the first trace 70. The aperture ratio thereof enables to be either smaller than 0.97 or further smaller than 0.5 and/or even smaller. For example, when the width D1 of the blind via 44 is 60 .mu.m, in order to make the area of the bind via 44 of the printed circuit board 51 be not smaller than the area of the blind via 44 of the printed circuit board 50 to keep the bonding strength between the first trace 70 and the first conductive material 95, the length H of blind via 44 of the first insulator 40 of the printed circuit board 51 is larger than 131 .mu.m (7,854/60) so that the aperture ratio of the blind via 44 of the first insulator 40 (i.e. the aperture ratio of the width D1 to the length H of the blind via 44 of printed circuit board 51) is about 0.46 (60/131), wherein if the length H of the blind via 44 of printed circuit board 51 is larger than 131 .mu.m, and the width D1 of the blind via 44 is still 60 .mu.m, then the aperture ratio of the blind via 44 will be even smaller than 0.46, the aperture ratio of the blind via 44 may enable to be between 0.01 and 0.79. At the same time, in order to prevent the first trace 70 from dropping into the blind via 44, it is fine that the width L1 of the first trace 70 is increased to 160 .mu.m. It will be fine too. In case of the width L1 of the first trace 70 being larger than 160 .mu.m, accordingly, the blind via 44 of the printed circuit board 51 with small ratio may allow more first traces 70 to be coupled with the printed circuit board 51 so as to make the printed circuit board more practical. It is good for the electronic industries, and It is to be understood that a blind via 44 of the first insulator 40 with both a real vent(s) 49 and a small ratio of the width D1 to the length H, then not only allows the short circuit problem may be prevented but more first traces 70 may also be coupled with the first insulator 40 of printed circuit board 51. Besides, no matter what the shape of the vent 49 is oval or other suitable shapes, the gates 47 enable to limit the metal particles 99 of the conductive material to flow into the vent 49 so as to bring the effects of the gate 49 (reference to the descriptions of FIGS. 2-1 to 2-3B). In FIGS. 7B-2 and 7B-3, the real blind 44 of the printed circuit board 51 may be protruded the side edge 33 of the first conductive pad 30 (shown as in FIG. 6C-1). The one (or two) vent(s) 49 may be arranged at the area excluding the side edge 33 of the first conductive pad 30 as demanded. The predetermined blind via area 46 and the predetermined vent area 48 may be replaced by the blind via 44 and the vent 49 respectively as demanded, or the vent 49 is excluded, or the at least a portion of the side edges 73, 33 of the first trace 70 or the first conductive pad 30 is bonded to the first insulator 40.

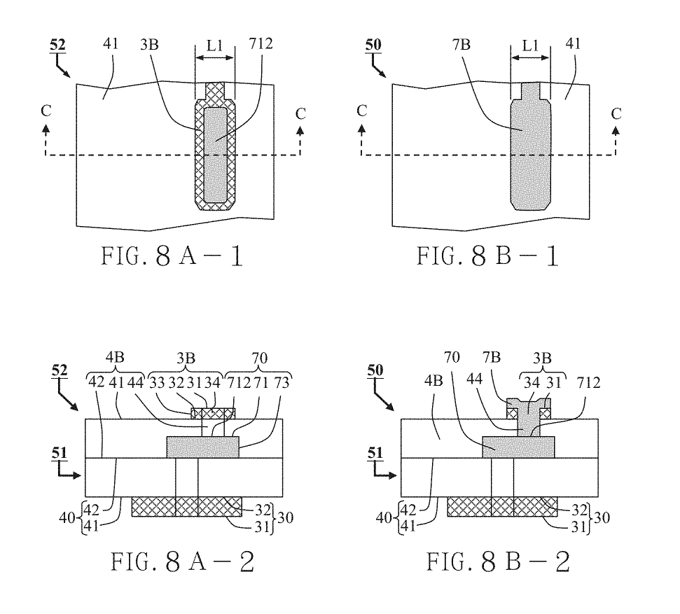

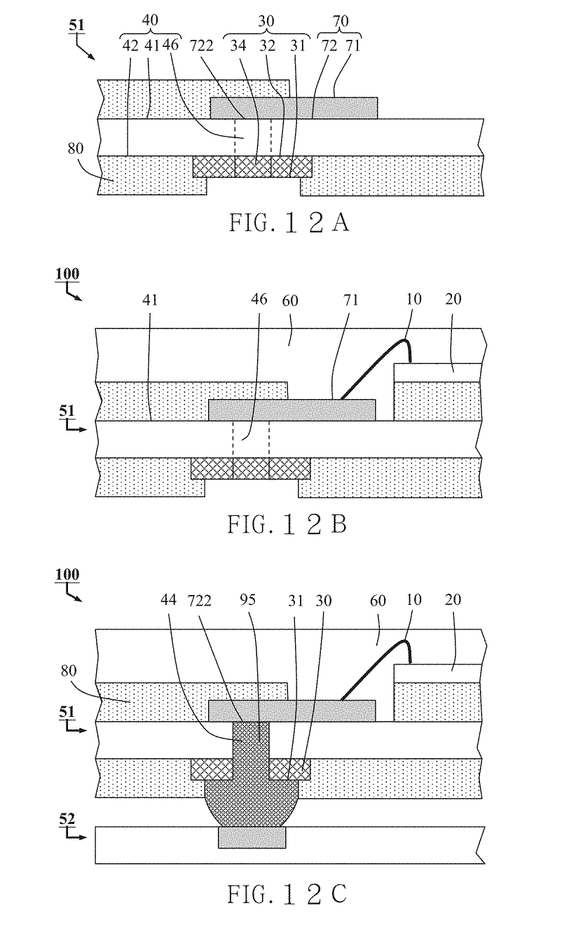

Referring to FIGS. 8A-1 to 8B-2, the FIGS. 8A-1 and 8B-1 are the top views of the printed circuit boards 52 and 50, and FIGS. 8A-2 and 8B-2 are the cross-sectional views of FIGS. 8A-1 and 8B-1 along line C-C. The printed circuit board 52 comprises the printed circuit board 51, a second insulator 4B, and a second conductive pad 3B. The characteristics and numbers of the printed circuit board 51 may reference to the descriptions of FIGS. 7B-1 to 7B-3. The difference therebetween is that a portion of the upper surface 71 of the first trace 70 of printed circuit board 51 is employed as a second upper surface 712. The second insulator 4B includes an upper surface 41, a lower surface 42, and a blind via 44 which is penetrated through the second insulator 4B. The lower surface 42 of the second insulator 4B is bonded to the first insulator 40 of the printed circuit board 51 and covered the first trace 70. The second upper surface 712 of the first trace 70 is exposed to the blind via 44 of the second insulator 4B for bonding to the first conductive material 95, second conductive trace 7B (shown as in FIG. 8B-1), or other suitable conductors. The second conductive pad 3B includes a side edge 33, an opening 34 (i.e. a through hole), an upper surface 31, and a lower surface 32. The second conductive pad 3B is arranged at the upper surface 41 of the second insulator 4B blind via 44. The opening 34 of the second conductive pad 3B is arranged corresponding to the second upper surface 712 of the first trace 70 so that the second upper surface 712 of the first trace 70 enables to be exposed to the opening 34 of second conductive pad 3B so as to be exposed to the atmosphere. The lower surface 32 is bonded to the second insulator 4B. The at least a portion of the side edge 33 of the second conductive pad 3B also enables to be bonded to the second insulator 4B as demanded. The upper surface 31 of the second conductive pad 3B may be provided for electrically connecting with outside (tin, nickel, conductive wire, conductive bump, lead, solder ball, or other suitable conductors). The printed circuit board 50 is composed of the printed circuit board 52 and the second trace 7B. The second trace 7B is made of copper, nickel, or other suitable conductors. The second trace 7B may be arranged at the upper surface 31 of the second conductive pad 3B by electroplating or other suitable processes. A portion of the second trace 7B is received in both the blind via 44 of the second insulator 4B and the opening 34 of the second conductive pad 3B in order to electrically connect to the second upper surface 712 of the first trace 70 blind via 44. Accordingly, the second conductive pad 3B may be electrically connected with the first trace 70 through the second trace 7B. In order to make the bendability between the second trace 7B and a side wall (not numbered) of the blind via 44 of the second insulator 4B better, a seed layer (not shown) may be arrange between the second trace 7B and the second upper surface 712 of the first trace 70 and between the second conductive pad 3B and the side wall of the blind via 44 of the second insulator 4B. in this manner, the seed layer is between the second trace 7B and the second upper surface 712 of the first trace 70 associated with the side wall of the blind via 44 of second insulator 4B, the side wall of the second conductive pad 3B and the upper surface 31 of second conductive pad 3B. According to above descriptions, the printed circuit board may further include at least one added insulator and an added conductive pad for stacking each element in order to become a multi-layer printed circuit board. The peripheral of the blind via 44 of the second insulator 4B may include the predetermined vent area 48 or the vent 49 shown as in FIGS. 2-1 to 7B-3. At least a portion of the second trace 7B of the printed circuit board 50 may be provided for electrically connecting with the member 20, the conductive means 10 (shown as in FIG. 11), and/or other suitable conductors.

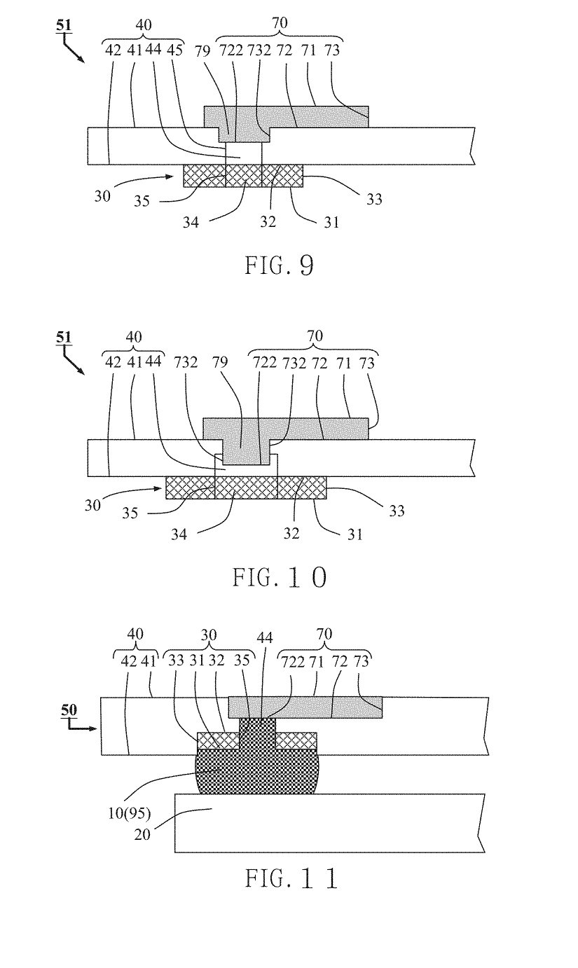

Referring to FIGS. 9 and 10, they are the cross-sectional views of the printed circuit board 51. The characteristics and numbers of the first insulator 40, the first trace 70, and the first conductive pad 30 of the printed circuit board 51 are the same as the printed circuit board 50 in FIGS. 7A-1 to 7A-3 which may reference to the descriptions of FIGS. 7A-1 to 7A-3. The difference therebetween is described as follows. The first trace 70 includes the upper surface 71, the lower surface 72, the first side edge 73, and the second side edge 732. A portion of the lower surface 72 may be employed as the second lower surface 722. The second side edge 732 is arranged between the lower surface 72 and the second lower surface 722. The second lower surface 722 may be convexly arranged at the lower surface 72 and formed a protruding portion 79, or the second lower surface 722 is concavely (shown as in FIG. 4-2) arranged at the lower surface 72. The embodiment is described by the protruding portion 79 for example. The protruding portion 79 is made of the conductive material which is the same or not the same as the first trace 70. The protruding portion 79 may shorten the distance between the second lower surface 722 of the first trace 70 and the first conductive pad 30 so that the first conductive material 95 received in the blind via 44 may be easier to bond to and electrically connect with the second lower surface 722 of the first trace 70 and further prevent from damage of open circuit. In FIG. 9, the second side edge 732 of the first trace 70 is totally covered by the first insulator 40 so that at least a portion of the second lower surface 722 is exposed to the blind via 44 of the first insulator 40. In FIG. 10, at least a portion of the second side 732 is not covered by the first insulator 40 so as to exposed to the blind via 44 of the first insulator 40 and make at least a portion of the second lower surface 722 of the first trace 70 be exposed to the blind via 44. In FIG. 10, the second side 732 may be totally exposed to the blind via 44 as demanded.

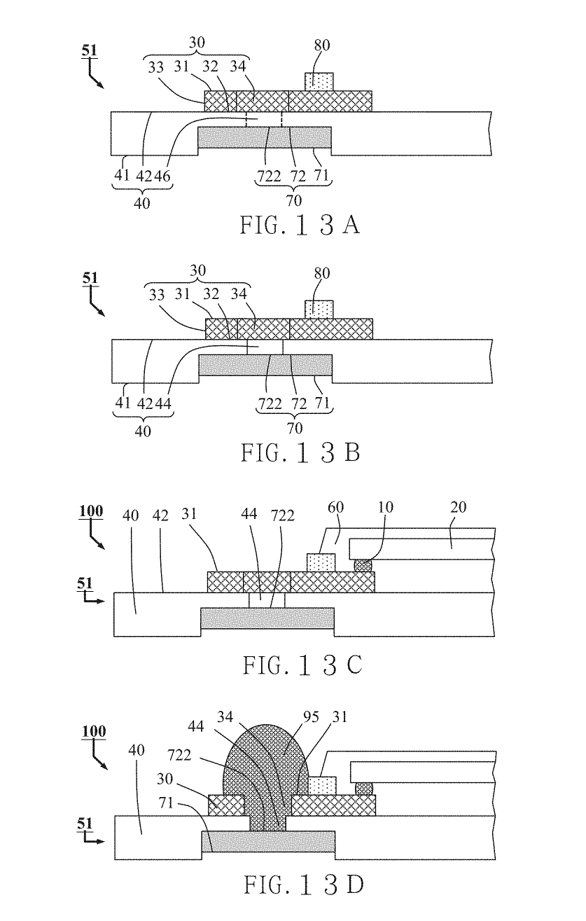

Referring to FIG. 11, it shows the cross-sectional view of the printed circuit board 50 which is combined with the member 20. The printed circuit board 50 comprises the first trace 70, the first insulator 40, the first conductive pad 30, and the member 20. The first trace 70 includes the upper surface 71, the lower surface 72, and the first side edge 73. A portion of the upper surface 71 of the first trace 70 may be provided for electrically connecting with the suitable conductors. A portion of the lower surface 72 is employed as the second lower surface 722. The first insulator 40 includes the upper surface 41, the lower surface 42, and the blind via 44. The first trace 70 is arranged at the upper surface 41 of the first insulator 40. At least a portion of the side edge 73 and the lower surface 72 of the first trace 70 are bonded to the first insulator 40 so that the upper surface 71 of the first trace 70 may be flatly, concavely, or convexly arranged at the upper surface 41 of the first insulator 40. The blind via 44 is arranged corresponding to the second lower surface 722 of the first trace 70 so that the second lower surface 722 of the first trace 70 may be exposed to the blind via 44. The first conductive pad 30 is arranged at the lower surface 42 of the first insulator 40 and includes the side edge 33, the upper surface 31, the lower surface 32, the opening 34, and the side wall 35. A portion of the upper surface 31 may be provided for electrically connecting with the suitable conductors. The opening 34 is arranged corresponding to the second lower surface 722 of the first trace 70. At least a portion of the side edge 33 and the lower surface 32 are bonded to the first insulator 40 so that the upper surface 31 of the first conductive pad 30 may be flatly, concavely, or convexly arranged at the lower surface 42 of the first insulator 40. The member 20 is arrange at the lower surface 42 of the first insulator 40 and connected with the printed circuit board 50 through the conductive mean 10 (95). When the member 20 is employed as a flip chip, the conductive mean 10 may be employed as a conductive bump. Nevertheless, in case that the member 20 is employed as a semiconductor package, module, or other suitable members, then the conductive mean 10 may be employed as a solder ball, solder paste, or other suitable conductors which are also one kind of the first conductive material 95. The conductive mean 10 (95) is arranged between the member 20 and the printed circuit board 50. A portion f the conductive mean 10 is received in the blind via 44 of the first insulator 40. The printed circuit board 50 is bonded to and electrically connected with the member 20, the second lower surface 722 of the first trace 70, and the first conductive pad 30 through the conductive means 10 (95). Besides, the encapsulant 60 (shown as in 13B) may be arranged at the surface of printed circuit board 50 and at least covered a portion of the member 20 to protect the member 20 as demanded. If the member 20 employed as a semiconductor package (numbered as 100 shown in FIG. 12B and/or FIG. 13C), then the member 20 further having at least a chip and/or a flip chip.

It is known by each printed circuit board in FIGS. 1-1 to 11 that the structure mainly comprises the first trace 70, the first insulator 40, and/or the first conductive pad 30. No matter what the first side edge 73 of the first trace 70 and/or the side edge 33 of the first conductive pad 30 in FIGS. 1-1 to 11 is bonded to the first insulator 40 or not, the first trace 70 is arranged at a surface (such as the upper surface 41) of the first insulator 40 and at least a portion of the second lower surface 722 of the first trace 70 is arranged corresponding to the blind via 44 of the first insulator 40. And in case that the printed circuit board has a first conductive pad 30, the first conductive pad 30 is arranged at the other surface (such as the lower surface 42) of the first insulator 40. When at least a portion of the opening 34 of the first conductive pad 30 is arranged corresponding to the lower surface 72 of the first trace 70, some electronic elements may be arranged in the printed circuit board as demanded. For example, the predetermined blind via area 46 is replaced by the blind via 44, the vent 49 and the gate 47 are arranged, the predetermined vent area 48 is replaced by the vent 49, a portion of the second lower surface 722 of the first trace 70 is exposed to the vent 49, a portion of the second lower surface 722 of the first trace 70 is not exposed to the bottom of the vent 49, the ratio of the width of the blind via 44 of the first insulator 40 to the length of the blind via 44 of the first insulator 40 may enable to be between 0.01 and 0.79, Both the second insulator 4B and the second conductive pad 3B is further arranged, the second insulator 4B, the second conductive pad 3B, and the second trace 7B are further arranged so that the printed circuit board enable to become a multi-layer circuit board, the first trace 70 includes the second side 732 so that the second lower surface 722 of the first trace 70 is concavely or convexly arranged at the lower surface 72, at least a portion of the side edge 23 of the member 20 and the lower surface 22 are bonded to the first insulator 40, the member 20 is electrically connected with the printed circuit boards 50, 51, 52 through the conductive means such as a conductive wire, conductive bump, solder ball, tin material, or other suitable conductors, the member 20 and the encapsulant 60 are arranged at the same surface of the printed circuit boards 50, 51, 52, the solder mask 80 may be (or not) arranged at any one surface of the first insulator 40 as demanded, the protective layer 90 is bonded to the trace or the conductive pad which is exposed to the atmosphere, a conductive material is provided for bonding to and electrically connecting with the first trace 70, a conductive film (reference to the descriptions of FIG. 8B-2) may be arranged at the side wall of the blind via 44, the second lower surface 722 of the first trace 70, and/or the conductive pad 30 for being good to bond to other suitable conductors, the carrier sheet is arranged at any one surface of the printed circuit boards 51, 52 described as in FIGS. 12A to 14C, or any one kind of the printed circuit board as above mentioned may be connected with the member 20 and the encapsulant 60 by the traces and the conductive pads shown as in FIGS. 12A to 14C. They may make the printed circuit board be used much broader.

The following descriptions in accordance with the present invention are described the drilling process for a predetermined blind via area of the first insulator of a printed circuit board being become a blind via of the first insulator of the printed circuit board basically, wherein the step(s) of drilling the predetermined via of the first insulator of printed circuit board can be provided either after the member, conductive means, and encapsulant are all arranged to the printed circuit board (refer to FIG. 12A to FIG. 12C and FIG. 14A to FIG. 14C) or before the member, conductive means, and encapsulant are all arranged to the printed circuit board (refer to FIG. 13A to FIG. 13D), The details are as following: Please, refer to FIG. 12A to 12C showing the drilling process for a predetermined blind via area 46 of the first insulator 40 of a printed circuit board 51 being become a blind via 44 of the first insulator of the printed circuit board 51, wherein the step of drilling the predetermined via area 46 of the first insulator 40 of printed circuit board 51 is provided after the member 20, conductive means 10, and encapsulant 60 are all arranged to the printed circuit board 51, the steps are as followed: Step (1). Shown in FIG. 12A, providing a printed circuit board 51, the characteristics and the numbers of the printed circuit board 51 are almost the same as them of the printed circuit board 51 in FIG. 7B-1 to 7B-3, there are two differences described as follows: The printed circuit board 51 in FIG. 12A includes solder masks 80 which are arranged at both the upper surface 41 and the lower surface 42 of the first insulator 40 respectively, and The predetermined blind via area 46 of the first insulator 40 of printed circuit board 51 is instead of the blind via 44 of printed circuit board shown in FIG. 7B-1 to 7B-3; Step (2). shown in FIG. 12B, providing a member 20, conductive means 10 and encapsulant 60 which are all arranged at the same surface of printed circuit board 51 (i.e. the upper surface 41 of the first insulator 40), wherein the member 20 is employed as a chip, the conductive means 10 are employed as conductive wires which are electrically connected the member 20 to the first traces 70 of printed circuit board 51 respectively, and the encapsulant 60 sealed the member 20, the conductive means 10 and the printed circuit board 51, as this result, a semiconductor package 100 is formed; Step (3). shown in FIG. 12C, providing a process of drilling (not shown) to remove the obstructers in the predetermined blind via area 46 so that the predetermined blind via area 46 becomes a real blind via (i.e. a through hole) 44 of the first insulator 40, in this manner, it allows the second lower surface 722 of the first trace 70 to be exposed to the blind via 44 of the first insulator 40 for external connection; and Step (4). Still referring to FIG. 12C, providing a first conductive material 95 to fill into the blind via 44 of the first insulator 40, wherein a portion of the first conductive material 95 received in the blind via 44 associated with the opening of the first conductive pad 30 and coupled with the second lower surface 722 of the first trace 70 in order to electrically connect the first trace 70, wherein the first conductive material is exposed to the atmosphere, Moreover, due to the printed circuit board 51 further having a first conductive pad 30, then an another portion of the first conductive material 95 enables to be coupled with the upper surface 31 associated with the side wall of the opening 34 of the first conductive pad 30, in this manner, it also allows the first trace 70 to be electrically connected to the first conductive pad 30 through the first conductive material 95, In addition, the first conductive material 95 is bonded to and electrically connected to a printed circuit board 52 which is considered to be employed as either any mentioned-above printed circuit board in accordance with the present invention or a conventional printed circuit board; Furthermore, the first conductive pad 30 of printed circuit board 51 is optional.

Please, refer to FIG. 13A to 13D showing the drilling process for a predetermined blind via area 46 of the first insulator 40 of a printed circuit board 51 being become a blind via 44 of the first insulator 40 of the printed circuit board 51, wherein the step of drilling the predetermined via area 46 of the first insulator 40 of printed circuit board 51 is provided before the member 20, conductive means 10, and encapsulant 60 are all arranged to the printed circuit board 51, the steps are as followed: Step (1). Shown in FIG. 13A, providing a printed circuit board 51, the characteristics and the numbers of the printed circuit board 51 are almost the same as them of the printed circuit board 52 in FIG. 6A-1 to 6C-2, there are three differences described as follows: The predetermined blind via area 46 of the first insulator 40 of printed circuit board 51 is instead of the blind via 44 of printed circuit board 52 shown in FIG. 6A-1 to 6C-2; The first conductive pad 30 of printed circuit board 51 which is instead of the first conductive pad 30 of printed circuit board 52 which is comprised of two metals; and There is a solder mask 80 bonded onto the upper surface 31 of the first conductive pad 30; Step (2). shown in FIG. 13B, providing a process of drilling (not shown) to remove the obstructers in the predetermined blind via area 46 so that the predetermined blind via area 46 becomes a real blind via (i.e. a through hole) 44 of the first insulator 40, in this manner, it allows the second lower surface 722 of the first trace 70 to be exposed to the blind via 44 of the first insulator 40 for external connection; Step (3). shown in FIG. 13C, providing a member 20, conductive means 10 and encapsulant 60 which are all arranged at the same surface of printed circuit board 51 (i.e. the lower surface 42 of the first insulator 40), wherein the member 20 is employed as a flip chip, the conductive means 10 are employed as conductive bumps which are electrically connected the member 20 to the first conductive pads 30 of printed circuit board 51 respectively, and the encapsulant 60 sealed the member 20, the conductive means 10 and the printed circuit board 51, as this result, a semiconductor package 100 is formed; and Step (4). Shown in FIG. 13D, providing a first conductive material 95 to fill into the blind via 44 of the first insulator 40, wherein a portion of the first conductive material 95 received in the blind via 44 associated with the opening of the first conductive pad 30 and coupled with the second lower surface 722 of the first trace 70 in order to electrically connect the first trace 70, Moreover, an another portion of the first conductive material 95 coupled with the upper surface 31 associated with the side wall of the opening 34 of the first conductive pad 30, wherein at least a portion of the first conductive material 95 is exposed to the atmosphere, wherein the distance between the top of the first conductive material 95 and the upper surface 31 of the first conductive pad 30 is larger than 40 .mu.m in this manner, Not only the first trace 70 but the first conductive pad 30 is electrically connected to the first conductive material 95.

Referring to FIG. 14A to 14C showing the drilling process for a predetermined blind via area 46 of the first insulator 40 of a printed circuit board 51 being become a blind via 44 of the first insulator 40 of the printed circuit board 51 are as followed: Step (1). Shown in FIG. 14A, providing two members 20 which are employed as chips; Step (2) still refer to FIG. 14A, providing two printed circuit boards 51, 52 The structures of the printed circuit boards 51, 52 are the same as the structure of the printed circuit board 50 shown in FIG. 1-2A, wherein each surface of printed circuit boards 51, 52 (i.e. the lower surface 42 of the first insulator 40) is coupled with a carrier sheet 88, 85. The carrier sheet 85 may be made of metal such as a copper foil etc. or an insulator such as adhesive tape etc. Moreover, a film 86 which is made of either metal or insulator may be further arranged between the carrier sheet 85 and the surface of printed circuit board 52 so that the bond ability between the carrier sheet 85 and the printed circuit board 52 may be more secure; The carrier sheet 88 is made of metal and is unitary to the first conductive pad 30, the carrier sheet 88 coupled with the lower surface 42 of the first insulator 40 of printed circuit board 51, wherein in case that both the carrier 88 and the first conductive pad 30 are unitary, then the peeling-off problem may be prevented; By means of the carrier sheets 51,52, the rigidity of printed circuit boards 51,52 enable to be enhanced before the encapsulant 60 is settled, in this manner, the risk of damage of printed circuit board due to insufficient rigidity may be prevented, and then each member 20 coupled with each surface (i.e. the upper surface 41 of the first insulator 40) of the printed circuit boards 51,52 respectively; Step (3) still refer to FIG. 14A, providing conductive means 10 and encapsulant 60 which are arranged and settled on the same surfaces of printed circuit boards 51,52 with members 20 respectively, the conductive means 10 are employed as conductive wires which are electrically connected each member 20 to the first traces 70 of each printed circuit board 51,52 respectively, and the encapsulant 60 sealed the member 20, the conductive means 10 and the printed circuit boards 51,52 respectively; Step (4) shown in FIG. 14B, At first, providing a peeling-off process (not shown; such as an etching process or other suitable process) to remove the carrier sheets 88,85 from the printed circuit boards 51,52 respectively, so that each upper surface 31 of the first conductive pad 30 is exposed to the atmosphere; Secondly, providing a process of drilling (not shown) to remove the obstructers in the predetermined blind via area 46 associated with the opening 34 of the first conductive pad 30 so that the predetermined blind via area 46 becomes a real blind via (i.e. a through hole) 44 of the first insulator 40, in this manner, it allows the second lower surface 722 of the first trace 70 to be exposed to the blind via 44 of the first insulator 40 for external connection; and Step (4). Shown in FIG. 14C, providing a conductive material to fill into the blind via 44 of the first insulator 40, wherein the conductive material is comprised of a group of metals such as solder ball, solder paste etc. and/or a group of conductive layer such as a nickel, tin, gold, palladium, copper or the like, and the group of metal is employed as a first conductive material 95, the group of conductive layer is employed as a second conductive material 9B; as shown in FIG. 14C, at first, a second conductive material 9B is filled into and received in the real via 44 of the first insulator 40 of printed circuit board 52 in order to be coupled with the second lower surface 722 of the first trace 70 of printed circuit board 52, then a first conductive material 95 also filled into the blind via 44 of printed circuit board 52, wherein a portion of the first conductive material 95 received in the blind via 44 associated with the opening 34 of the first conductive pad 30 and coupled with the second conductive material 9B, meanwhile an another portion of the first conductive material 95 coupled with the upper surface 31 of the first conductive pad 30, so that the first trace 70 of printed circuit board 52 can be electrically connected to the first conductive pad 30 through the conductive material which is comprised of both the first conductive material 95 and the second conductive material 9B, wherein the first conductive material 95 is exposed to the atmosphere; By means of the second conductive material 9B, the distance between the second lower surface 722 of the first trace 70 and the first conductive pad 30 is shortened, then it is easier for the first conductive material 95 to be electrically connected to the first conductive pad 30; The conductive material coupled with the printed circuit board 51 is comprised of the first conductive material 95 exclusively; Moreover, in case that the first conductive material 95 of printed circuit board 52 is omitted, then the conductive material of printed circuit board 52 is comprised of the second conductive material 9B exclusively. In addition, the first conductive pads 30 coupled with the lower surface 42 of insulator of printed circuit boards 51, 52 are optional; either the carrier sheet 85 or the carrier sheet 88 enables to be stacked a further carrier sheet(s), Moreover, in case that each carrier sheet 85, 88 further having an opening 84 which is corresponding to each blind via 44, then the carrier sheet enables to be always coupled with the printed circuit board 52, 51, so that the carrier sheet is/are not removed from the printed circuit board 52, 51 for enhancing the rigidity of the printed circuit board 52, 51 as demanded; In addition, the process for the predetermined blind via area 46 of the first insulator 40 being become a via 44 as shown in FIG. 14A-14C, wherein the side edge (numbered 23 in FIG. 3) of member 20 may also be coupled with the first insulator 40 and electrically connected to the printed circuit board 51, 52 as demanded, and then being sealed by the encapsulant 60.

The printed circuit board structure using the process of electrically connecting the trace of the printed circuit board structure with the conductive pad after combining the printed circuit board structure with the encapsulant in FIGS. 12A to 14C may be replaced by any one of the printed circuit board structure in FIGS. 1-1 to 14C as demanded. The member 20 and the encapsulant 60 may be arranged at any one surface of the printed circuit board and the carrier sheet 85, 88 is arranged at the other surface of the printed circuit board as demanded.

The foregoing descriptions are merely the exemplified embodiments of the present invention, where the scope of the claim of the present invention is not intended to be limited by the embodiments. Any equivalent embodiments or modifications without departing from the spirit and scope of the present invention are therefore intended to be embraced.

With reference to FIG. 15A, in another embodiment, the printed circuit board 50 comprises a first insulator 40 which includes an upper surface 41, a lower surface 42, and a blind via 44 passing through the first insulator 40. The first insulator 40 is made of insulation material, such as any one of resin, polymide, and/or epoxy etc., in this embodiment, the blind via 44 of the first insulator 40 of the printed circuit board 50 does not include a vent(s) 49 as required, and wherein the blind via of the first insulator 40 of the printed circuit board 50 enables to include a vent(s) 49 as required too (the advantages of the vent(s) 49 of the blind via 44 of the first insulator 40 are described in the descriptions of FIG. 2-2 and/or the descriptions of FIG. 7B-1 to FIG. 7B-3). The printed circuit board 50 further comprises a first trace 70 which includes an upper surface 71, a lower surface 72, a first side edge 73, and a terminal 724 located on a part of the lower surface 72, wherein the first surface 72 of the first trace 70 is connected with the upper surface 41 of the first insulator 40, and the terminal 724 is corresponding to the blind via 44 of the first insulator 40, in this manner, the terminal 724 exposes inside the blind via 44 of the first insulator 40 for external connection. The printed circuit board 50 further comprises a first conductive pad 30 which includes an upper surface 31, a lower surface 32, a side edge 33, and an opening 34, wherein a part of the upper surface 31 of the first conductive pad 30 is a coupling zone 316 configured to connect with a solder mask 80, and the opening 34 of the first conductive pad 30 passes through the first conductive pad 30, wherein both the side edge 33 and the lower surface 32 of the first conductive pad 30 are connected with the first insulator 40, thus enhancing the conjunction that the first conductive pad 30 is connected with the first insulator 40 of the printed circuit board 50, and the upper surface 31 of the first conductive pad 30 exposes outside the lower surface 42 of the first insulator 40 for being electrically connected to an external connection, and the opening 34 of the first conductive pad 30 corresponds to the terminal 724 of the first trace 70 so that the terminal 724 exposes inside the blind via 44 of the first insulator 40 for being electrically connected to the external connection, wherein due to the side edge 33 of the first conductive pad 30 is connected with the first insulator 40, then 1). the printed circuit board 50 is a two-layered printed circuit board, therefore, the thickness of the printed circuit board 50 enables to becomes thinner, it is convenient for the printed circuit board 50 to be used in the electronic industries; Furthermore, in accordance with the printed circuit board 50 of the present invention, the first side edge 73 of the first trace 70 enables to be connected with the first insulator 40 (refer to FIG. 3) too, consequently, both the side edge 33 of the first conductive pad 30 and the first side edge 73 of the first trace 70 are connected with the first insulator 40, in this manner, the printed circuit board 50 becomes only a one-layered printed circuit board, therefore, the thickness of the printed circuit board 50 enables to be even more thinner, then it is more convenient for the printed circuit board 50 to be used in the electronic industries; and 2). the areas of the first conductive pad 30 contacted with the first insulator 40 are increased, due to Not only the lower surface 32 but the side edge 33 of the first conductive pad 30 also are connected with the first insulator 40, thus connecting the first conductive pad 30 and the first insulator 40 securely to avoid the first conductive pad 30 peeling off from the first insulator 40. For example, when the first conductive pad 30 is connected with the first conductive material 95 (i.e., the solder ball) as shown in FIG. 14C and the first conductive material 95 is stricken by an external force such as a collision, wherein, By means of the side edge 33 of the first conductive pad 30 being coupled with the first insulator 40, the first conductive pad 30 enables to be connected with the first insulator 40 more firmly, then the first conductive pad 30 enables to be not peeled off from the first insulator 40. In this embodiment, the printed circuit board 50 further includes a solder mask 80, wherein the solder mask 80 is made of insulation material (such as an insulation layer), and the solder mask 80 includes an opening 84 passing through the solder mask 80 and corresponding to the terminal 724 of the first trace 70, wherein the solder mask 80 is connected with both the lower surface 42 of the first insulator 40 and the coupling zone 316 of the upper surface 31 of the first conductive pad 30, wherein the solder mask 80 is optional, moreover, the first insulator 40 has a thickness T40, and the blind via 44 has a width D44, wherein the ratio of the thickness T40 of the first insulator 40 to the width D44 of the first insulator 40 is not lager than 0.5 so as to enhance the rigidity of the first insulator 40, in addition, the lower surface 42 of the first insulator 40 also enables to be comprised of the first traces (not shown) so as to increase a number of the first traces 70 on the printed circuit board 50 as required.

Referring to FIG. 15B, a printed circuit board 51 comprises a first insulator 40 which includes an upper surface 41, a lower surface 42, and a predetermined blind via 46 having a received element 40k accommodated in the predetermined blind via 46, wherein the received element 40k is defined by a part of the first insulator 40, and the first insulator 40 of the printed circuit board 51 enables to include a predetermined vent area (refer to FIG. 2-1; numeral“48”) as required. The printed circuit board 51 further comprises a first trace 70 which includes an upper surface 71, a lower surface 72, a first side edge 73, and a terminal 724 located on a part of the lower surface 72, the lower surface 72 of the first trace 70 is connected with the upper surface 41 of the first insulator 40, wherein the terminal 724 corresponds to the predetermined blind via 46 of the first insulator 40 and is connected with the received element 40k of the predetermined blind via 46, and wherein the received element 40k is accommodated in the predetermined blind via 46 temporarily, the terminal 724 is connected with the received element 40k temporarily too, (i.e., the received element 40k will be removed eventually), wherein when the received element 40k is removed, the terminal 724 will enable to be for being electrically connected to the external connection. The printed circuit board 51 further comprises a first conductive pad 30 which includes an upper surface 31, a lower surface 32, a side edge 33, and an opening 34, the opening 34 passes through the first conductive pad 30, wherein both the side edge 33 and the lower surface 32 of the first conductive pad 30 are connected with the first insulator 40, and the upper surface 31 of the first conductive pad 30 exposes outside the lower surface 42 of the first insulator 40 for being electrically connected to the external connection, the opening 34 of the first conductive pad 30 corresponds to both the predetermined blind via 46 and the terminal 724 of the first trace 70 so that there is a part of the received element 40k accommodated in the opening 34. In this embodiment, the printed circuit board 51 further comprises a solder mask 80 which includes a predetermined opening 86 having a received element 80k, wherein the received element 80k is defined by a part of the solder mask 80, and a surface of the solder mask 80 is connected with the lower surface 42 of the first insulator 40, the upper surface 31 of the conductive pad 30, and the received element 40k, wherein the predetermined opening 86 corresponds to the opening 34 of the first conductive pad 30, the predetermined blind via 46 of the first insulator 40, and the terminal 724. The received element 80k is accommodated in the predetermined opening 86 temporarily and will be removed eventually. The printed circuit board 51 further comprises a carrier C made of at least one copper foil and is connected with the solder mask 80. For example, the carrier C includes a copper foil Ca and a prepreg Cb, wherein a surface of the prepreg Cb is connected with the copper foil Ca, and the carrier C is coupled with the solder mask 80 by using the copper foil Ca, wherein a rigidity of the printed circuit board 51 is enhanced by ways of the carrier C to prevent the printed circuit board 51 from being bent and broken to damage in a packaging process. Furthermore, the other surface of the prepreg Cb enables to be connected with another copper foil Ce so as to change the rigidity of the printed circuit board 51. In another embodiment, the carrier C does not include the other copper foil Ce as required. In other words, the carrier C only includes the copper foil Ca and the prepreg Cb.

With reference to FIG. 15C, a difference of the printed circuit board 50 of FIG. 15C from that of the printed circuit board 51 of FIG. 15B comprises: the prepreg Cb of the carrier C having a through hole Cb4, a cross section of which is formed in any one of a rectangle shape, a circle shape, a strip shape, and/or a polygon shape. Thereby, a coefficient of thermal expansion (CTE) of the carrier C is adjustable by ways of the through hole Cb4 so as to improve a bendability of the printed circuit board 50. As illustrated in FIG. 15D, a difference of the printed circuit board 50 of FIG. 15D from that of the printed circuit board 51 of FIG. 15B comprises: a carrier C1 including a detachable copper foil C13, a prepreg C12, and the carrier C of FIG. 15B, wherein in this embodiment, the carrier C is served as a copper clad laminate, and wherein the detachable copper foil C13 is connected with the carrier C by using the prepreg C12, and the detachable copper foil C13 has two connection parts which are connected by a release layer (not shown), wherein one of the two connection parts is employed as a connection layer C131, and the other connection parts is employed as a removal layer C132. The carrier C1 is connected with the solder mask 80 of the printed circuit board 50 by ways of the connection layer C131 of the carrier C1, thus enhancing the rigidity of the printed circuit board 50 by using the carrier C1 comprised of the detachable copper foil C13, the prepreg C12, and the carrier C. Preferably, the carrier C1 is detachable easily by using the removal layer 132 of the detachable copper foil C13 in the packaging process, thus detaching the carrier C1 from the solder mask 80 efficiently and completely, in addition, the thickness of the detachable copper foil C131 enables to be larger than the thickness of the removal layer C132 or the thickness of the detachable copper foil C131 enables to be smaller than the thickness of the removal layer C132 as required.

The disclosed structure of the invention has not appeared in the prior art and features efficacy better than the prior structure which is construed to be a novel and creative invention, thereby filing the present application herein subject to the patent law.

What is claimed is:

1. A printed circuit board comprising:
a first insulator including an upper surface, a lower surface, and a blind via, wherein the blind via passing through the first insulator;
a first trace including an upper surface, a lower surface, a first side edge, and a terminal, wherein the terminal is located on a part of the lower surface of the first trace, the lower surface of the first trace is connected with the upper surface of the first insulator, wherein the terminal corresponds to and exposes inside the blind via of the first insulator to be electrically connected with an external connection; and
a first conductive pad including an upper surface, a lower surface, a side edge, and an opening passing through the first conductive pad, wherein both the side edge and the lower surface of the first conductive pad are connected with the first insulator, and the upper surface of the first conductive pad exposes outside the lower surface of the first insulator to be electrically connected with an external connection, wherein the opening of the first conductive pad corresponds to the terminal of the first trace so that the terminal exposes inside the blind via of the first insulator.

2. The printed circuit board as claimed in claim 1 further comprising a solder mask which includes an opening corresponding to the terminal of the first trace, wherein the solder mask is connected with the lower surface of the first insulator.

3. The printed circuit board as claimed in claim 2, wherein a part of the upper surface of the first conductive pad is a coupling zone, and wherein the solder mask is also connected with the coupling zone of the upper surface of the conductive pad.

4. The printed circuit board as claimed in claim 1, wherein the first insulator has a thickness, and the blind via of the first insulator has a width, and wherein a ratio of the thickness of the first insulator to the width of the blind via of the first insulator is not lager than 0.5.

5. The printed circuit board as claimed in claim 1, wherein the blind via of the first insulator further has a vent located adjacent to and communicating with the blind via.

6. The printed circuit board as claimed in claim 1, wherein the blind via of the first insulator has both a width and a length, the width of the first insulator is shorter than the length of the first insulator, and wherein an aperture ratio of the blind via of the first insulator is between 0.01 and 0.79.

7. The printed circuit board as claimed in claim 1, wherein the first side edge of the first trace is connected with the first insulator.
